(19) United States
(12) Patent Application Publication
(10) Pub. No.: US 2026/0122767 A1
(43) Pub. Date: Apr. 30, 2026

(54) SUBSTRATE CONNECTION STRUCTURE, ANTENNA SUBSTRATE, AND DISPLAY DEVICE

(71) Applicants: Murata Manufacturing Co., Ltd., Nagaokakyo-shi (JP); Dai Nippon Printing Co., Ltd., Tokyo (JP)

(72) Inventors: Hayato NAKAMURA, Nagaokakyo-shi (JP); Kaoru SUDO, Nagaokakyo-shi (JP); Yuya DOKAI, Nagaokakyo-shi (JP); Kazushige SATO, Nagaokakyo-shi (JP); Kengo ONAKA, Nagaokakyo-shi (JP); Shuji KAWAGUCHI, Tokyo (JP); Kazuki KINOSHITA, Tokyo (JP)

(73) Assignees: Murata Manufacturing Co., Ltd., Nagaokakyo-shi (JP); Dai Nippon Printing Co., Ltd., Tokyo (JP)

(21) Appl. No.: 19/430,275

(22) Filed: Dec. 23, 2025

Related U.S. Application Data
(63) Continuation of application No. PCT/JP2024/023560, filed on Jun. 28, 2024.

(30) Foreign Application Priority Data
Jul. 3, 2023 (JP) 2023-109392

(51) Int. Cl. H05K 1/02; H01Q 1/22; H01Q 1/38; H05K 1/11; H05K 1/14

(52) U.S. Cl. CPC H05K 1/0242; H01Q 1/2283; H01Q 1/38; H05K 1/024; H05K 1/0243; H05K 1/116; H05K 1/144; H05K 2201/042; H05K 2201/09227; H05K 2201/09236; H05K 2201/09681

(57) ABSTRACT

A substrate connection structure includes a first substrate, a second substrate partially facing the first substrate, and a transmission line extending over the first and second substrates. The transmission line includes a first transmission line on a first surface of the first substrate facing the second substrate, a second transmission line on a second surface of the second substrate facing the first substrate. A through-hole wiring is located at a position not overlapping with the second transmission line. A connection conductor is on the first surface and connects to the through-hole wiring. The first transmission line connect the connection conductor to the second transmission line. A size of the first transmission line is smaller than a size of the connection conductor in a direction orthogonal to a direction in which the first transmission line extends.

### CROSS-REFERENCE TO RELATED APPLICATIONS

This application is a continuation of International Application No. PCT/JP2024/023560, filed on Jun. 28, 2024, which claims priority to Japanese Patent Application No. 2023-109392, filed on Jul. 3, 2023. The entire disclosures of the prior applications are hereby incorporated by reference in their entirety.

### TECHNICAL FIELD

The present disclosure relates to a substrate connection structure, an antenna substrate, and a display device.

### BACKGROUND ART

JP 2008-60329 A discloses a connection structure of a printed substrate as a kind of substrate connection structure. The connection structure of the printed substrate disclosed in JP 2008-60329 A includes a plurality of printed substrates having a connection portion pattern formed on a surface of the printed substrate. At least one of the plurality of printed substrates is disposed such that connection portions of the printed substrates face each other. Connection portion patterns facing each other are connected by reflow-cured solder. Further, JP 2008-60329 A discloses that in at least one printed substrate, a through hole extending from a surface of the connection portion pattern facing the solder to a surface opposite to a side on which the connection portion pattern is located is formed.

### Patent Documents

Patent Document 1: JP 2008-60329 A

### SUMMARY

According to an aspect of the present disclosure, a substrate connection structure includes a first substrate, a second substrate partially facing the first substrate when viewed in a thickness direction of the first substrate, and a transmission line extending over the first and second substrates. The transmission line includes a first transmission line on a first surface of the first substrate facing the second substrate, a second transmission line on a second surface of the second substrate facing the first substrate, a through-hole wiring located at a position not overlapping with the second transmission line when viewed in a thickness direction of the first substrate and exposed to the first surface, and a connection conductor on the first surface and connected to the through-hole wiring. The first transmission line extends from the connection conductor to the second transmission line and is connected to the second transmission line. A size of the first transmission line is less than a size of the connection conductor in a second direction orthogonal to a first direction in which the first transmission line extends from the connection conductor to the second transmission line when viewed in a thickness direction of the first substrate.

According to another aspect of the present disclosure, an antenna substrate includes the above substrate connection structure and a radiation electrode provided on a second substrate and connected to the second transmission line.

According to still another aspect of the present disclosure, a display device includes the antenna substrate and a display disposed on a side of the second substrate opposite to the first substrate.

### BRIEF DESCRIPTION OF DRAWINGS

FIG. 1 is a perspective view of a substrate connection structure according to a first embodiment;

FIG. 2 is a plan view of the substrate connection structure according to the first embodiment;

FIG. 3 is a cross-sectional view taken along the line Y-Y of FIG. 2;

FIG. 4 is a cross-sectional view taken along the line X-X of FIG. 2;

FIG. 5 is a perspective view of an antenna substrate according to a second embodiment;

FIG. 6 is a plan view of an antenna substrate according to the second embodiment;

FIG. 7 is a cross-sectional view taken along the line Y-Y of FIG. 6;

FIG. 8 is a cross-sectional view taken along the line X-X of FIG. 6;

FIG. 9 is a plan view of a wiring pattern of a first layer of a first substrate according to the second embodiment;

FIG. 10 is a plan view of a wiring pattern of a second layer of the first substrate according to the second embodiment;

FIG. 11 is a plan view of a wiring pattern of a third layer of the first substrate according to the second embodiment;

FIG. 12 is a plan view of a second substrate of the antenna substrate according to the second embodiment;

FIG. 13 is a cross-sectional view of an antenna substrate according to a third embodiment;

FIG. 14 is a plan view of a wiring pattern of a second layer of the first substrate according to the third embodiment;

FIG. 15 is a plan view of a second transmission line and a radiation electrode of an antenna substrate according to a fourth embodiment;

FIG. 16 is a cross-sectional view of a display device according to a fifth embodiment;

FIG. 17 is a plan view of a display device of which a part is omitted according to the fifth embodiment; and

FIG. 18 is a plan view of a second transmission line and a radiation electrode according to the fifth embodiment.

### DETAILED DESCRIPTION

In the connection structure of the printed substrate disclosed in JP 2008-60329 A, the connection portion pattern is connected to the through hole. In general, when a transmission line such as a connection portion pattern and a through-hole wiring such as a through hole are connected, a connection conductor such as a land that has a diameter greater than that of the through-hole wiring is used in consideration of positional deviation between the through-hole wiring and the transmission line.

However, when the connection conductor is used, it is necessary to set a size of the transmission line based on the size of the connection conductor. Accordingly, an adjustment width of the size of the transmission line is limited, which can hinder adjustment of the impedance of the transmission line.

The present disclosure provides a substrate connection structure, an antenna substrate, and a display device that can easily adjust impedance of a transmission line.

### 1. Embodiments

Hereinafter, embodiments of the present disclosure will be described with reference to the drawings where appropriate. However, the following embodiments are merely examples for explaining the present disclosure, and are not intended to limit the present disclosure to the following content (e.g., shapes, dimensions, arrangement and the like, of components). Positional relationships such as up, down, left, and right are based on the positional relationships shown in the drawings, unless otherwise specified. Each figure described in the following embodiments is a schematic diagram, and the ratios of size and thickness of each component in each figure do not necessarily reflect the actual dimensional ratios. Furthermore, the dimensional ratios of each element are not limited to the ratios shown in the drawings.

In the following description, if it is necessary to distinguish a plurality of components from each other, prefixes, such as, “first”, “second”, or the like are attached to names of such components. However, if these components can be distinguished from each other by reference signs attached to those components, such prefixes, such as, “first”, “second”, or the like, may be omitted in consideration of readability of texts.

Note that, in the following description, if it is necessary to distinguish a plurality of components from each other, suffixes, such as, “−1”, “−2”, or the like are attached to reference signs of such components. if there is no need to distinguish such components from each other, such suffixes, such as, “−1”, “−2”, or the like, may be omitted in consideration of readability of texts.

### 1.1 First Embodiment

### [1.1.1 Configuration]

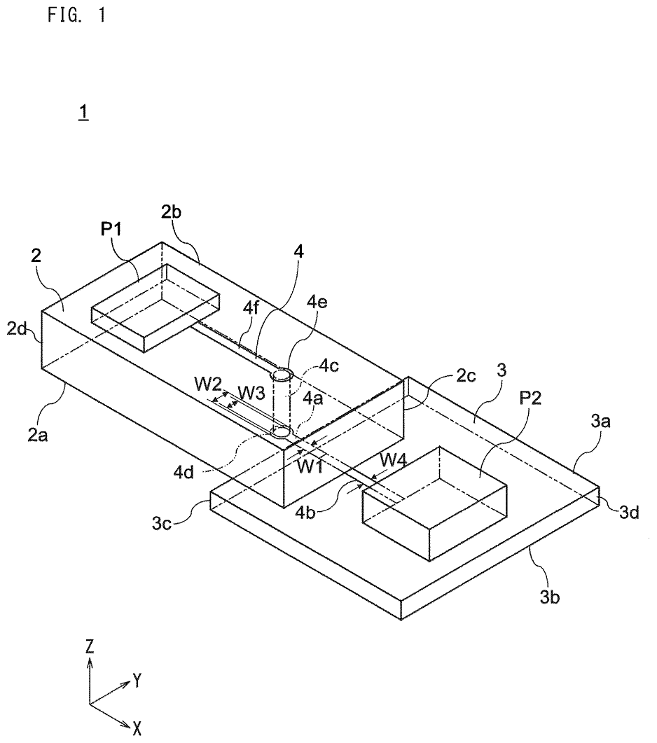

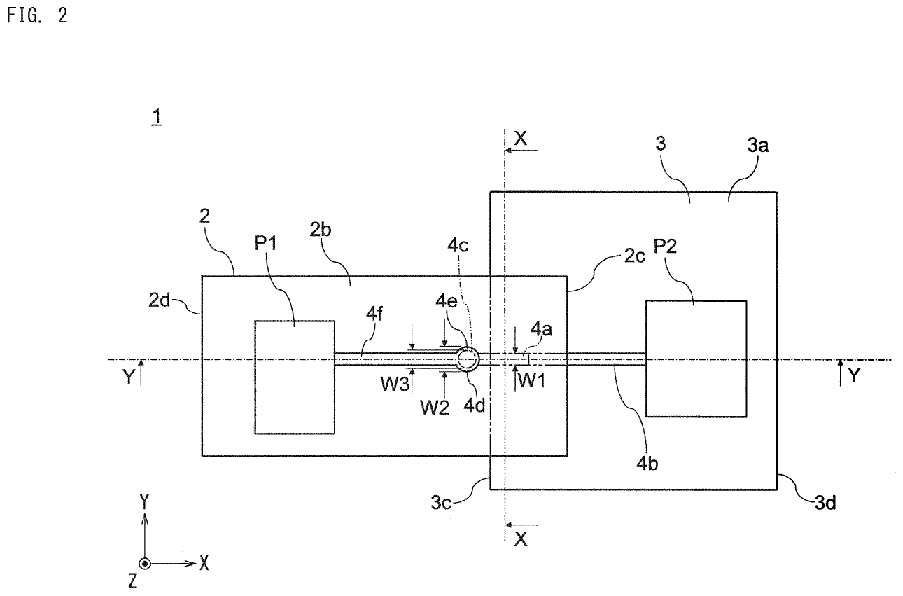

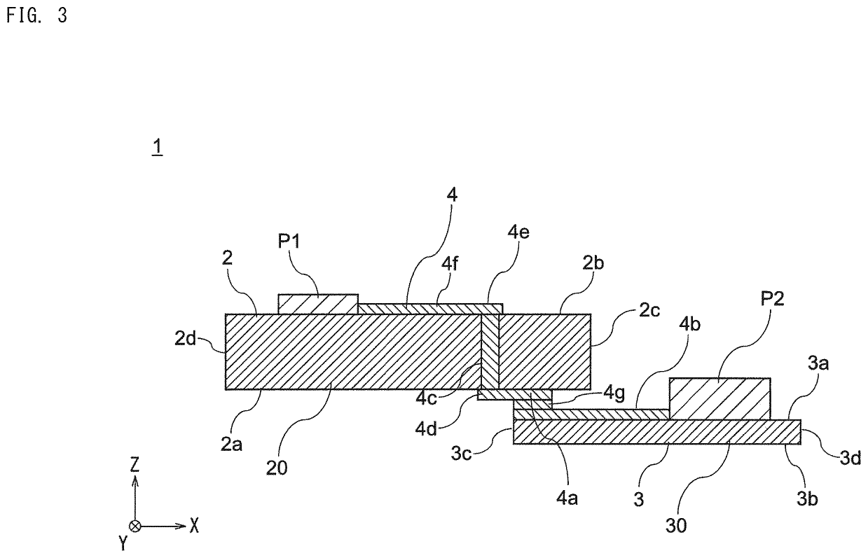

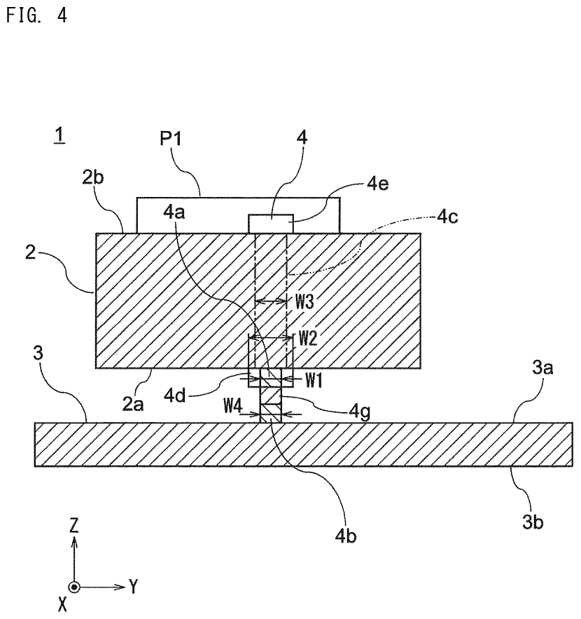

FIG. 1 is a perspective view of a substrate connection structure 1 according to a first embodiment. FIG. 2 is a plan view of the substrate connection structure 1. FIG. 3 is a cross-sectional view taken along the line Y-Y of FIG. 2. FIG. 4 is a cross-sectional view taken along the line X-X of FIG. 2. In the present embodiment and the following description, an XYZ orthogonal coordinate system illustrated in FIGS. 1 to 4 is used simply for brevity.

The substrate connection structure 1 includes a first substrate 2, a second substrate 3, and a transmission line 4.

The first substrate 2 has a thickness. In the present embodiment, a thickness direction of the first substrate 2 is the Z direction. The first substrate 2 includes a dielectric layer 20. The dielectric layer 20 has a first surface 2a and a third surface 2b opposite to the first surface 2a. The first and third surfaces 2a and 2b are both surfaces of the first substrate 2 in the thickness direction. The first and third surfaces 2a and 2b are main surfaces of the first substrate 2, and normal directions of these surfaces match the thickness direction of the first substrate 2. Therefore, the thickness direction of the first substrate 2 may be referred to as a normal direction of the first substrate 2. The first substrate 2 has first and second ends 2c and 2d opposite to each other in a first direction (the X direction) orthogonal to the thickness direction. The first end 2c of the first substrate 2 is directed toward the second substrate 3.

The second substrate 3 has a thickness. In the present embodiment, a thickness direction of the second substrate 3 is the Z direction. That is, the thickness direction of the second substrate 3 matches the thickness direction of the first substrate 2. The second substrate 3 includes a dielectric layer 30. The dielectric layer 30 has a second surface 3a and a fourth surface 3b opposite to the second surface 3a. The second and fourth surfaces 3a and 3b are both surfaces of the second substrate 3 in the thickness direction. The second substrate 3 has first and second ends 3c and 3d opposite to each other in a first direction (the X direction) orthogonal to the thickness direction. The first end 3c of the second substrate 3 is directed toward the first substrate 2.

The first and second substrates 2 and 3 have a rectangular plate shape. The first and second substrates 2 and 3 are, for example, dielectric substrates. Examples of the dielectric substrate include a low-temperature co-fired ceramic (LTCC) multilayer substrate, a multilayer resin substrate formed by stacking a plurality of resin layers formed of a resin such as epoxy or polyimide, a multilayer resin substrate formed by stacking a plurality of resin layers formed of a liquid crystal polymer (LCP) having a lower dielectric constant, a multilayer resin substrate formed by stacking a plurality of resin layers formed of a fluorine-based resin, and a ceramic multilayer substrate other than LTCC.

As illustrated in FIG. 2, the first and second substrates 2 and 3 are disposed so as to partially overlap each other when viewed in the thickness direction of the first substrate 2. That is, the first and second substrates 2 and 3 are not disposed such that one of the first and second substrates 2 and 3 is included in the other substrate when viewed in the thickness direction of the first substrate 2. The first surface 2a of the first substrate 2 and the second surface 3a of the second substrate 3 partially face each other. In particular, the end on the first end 2c side of the first surface 2a of the first substrate 2 faces the end on the first end 3c side of the second surface 3a of the second substrate 3. As described above, when viewed in the thickness direction of the first substrate 2, the ends of the first and second substrates 2 and 3 face each other. Accordingly, when viewed in the thickness direction of the first substrate 2, a distance between the ends on the opposite side of the first and second substrates 2 and 3 can be increased, and a line length of the transmission line 4 can be increased.

The transmission line 4 extends over the first and second substrates 2 and 3. In the present embodiment, the transmission line 4 is used to transmit a signal between an electronic component P1 mounted on the third surface 2b of the first substrate 2 and an electronic component P2 mounted on the second surface 3a of the second substrate 3. The signal is a high frequency signal in the present embodiment. The electronic components P1 and P2 are not particularly limited, and examples thereof include an IC, a connector, a filter, and an antenna element. The transmission line 4 is a conductor pattern. A known material can be used as the material of the transmission line 4.

The transmission line 4 includes a first transmission line 4a, a second transmission line 4b, a through-hole wiring 4c, connection conductors 4d and 4e, a third transmission line 4f, and a connection layer 4g. As illustrated in FIGS. 1 to 3, the first transmission line 4a, the through-hole wiring 4c, the connection conductors 4d and 4e, and the third transmission line 4f are formed on the first substrate 2, and the second transmission line 4b is formed on the second substrate 3.

The second transmission line 4b is located on the second surface 3a of the second substrate 3 facing the first substrate 2. The second transmission line 4b extends from the first end 3c of the second substrate 3 to the second end 3d. The second transmission line 4b has a linear shape. An end of the second transmission line 4b on the first end 3c side of the second substrate 3 is used as an electrode for connection with the first transmission line 4a. The second transmission line 4b is connected to the first transmission line 4a at an end on the first end 3c side, and is connected to the electronic component P2 at an end on the second end 3d side.

The first transmission line 4a is located on the first surface 2a of the first substrate 2 facing the second substrate 3. The third transmission line 4f is located on the third surface 2b of the first substrate 2 opposite to the second substrate 3. The through-hole wiring 4c and the connection conductors 4d and 4e connect the first and third transmission lines 4a and 4f on the first and third surfaces 2a and 2b different from each other.

The through-hole wiring 4c penetrates through the first substrate 2 to be exposed to the first and third surfaces 2a and 2b of the first substrate 2. The through-hole wiring 4c is a so-called through-hole wiring.

The connection conductor 4d is located on the first surface 2a of the first substrate 2 and is connected to the through-hole wiring 4c. The connection conductor 4e is located on the third surface 2b of the first substrate 2 and connected to the through-hole wiring 4c. The connection conductors 4d and 4e may be, e.g., so-called lands. More specifically, the connection conductors 4d and 4e are located at positions overlapping the through-hole wiring 4c when viewed in the thickness direction of the first substrate 2. In the present embodiment, diameters of the connection conductors 4d and 4e are greater than a diameter of the through-hole wiring 4c.

The first transmission line 4a extends from the connection conductor 4d to the first end 2c side of the first substrate 2. That is, the first transmission line 4a extends from the connection conductor 4d to the second transmission line 4b. The first transmission line 4a has a linear shape. An end of the first transmission line 4a on the first end 2c side of the first substrate 2 is used as an electrode for connection with the second transmission line 4b. The first transmission line 4a is connected to the second transmission line 4b at an end on the first end 2c side, and is connected to the connection conductor 4d at an end on the second end 2d side.

The third transmission line 4f extends from the connection conductor 4d to the second end 2d of the first substrate 2. The third transmission line 4f has a linear shape. The third transmission line 4f is connected to the connection conductor 4e at the end on the first end 2c side, and is connected to the electronic component P1 at the end on the second end 2d side.

As illustrated in FIGS. 3 and 4, the connection layer 4g is located between the first and second transmission lines 4a and 4b, and couples the first and second transmission lines 4a and 4b. The connection layer 4g is formed of, for example, solder. A material of the connection layer 4g is not limited to solder as long as the connection layer 4g has conductivity and can couple the first and second transmission lines 4a and 4b. For example, the connection layer 4g may be configured using an anisotropic conductive film.

In the transmission line 4, as illustrated in FIG. 2, the through-hole wiring 4c is located at a position not overlapping the second transmission line 4b when viewed in the thickness direction of the first substrate 2. In particular, the through-hole wiring 4c is located at a position not overlapping the second substrate 3 when viewed in the thickness direction of the first substrate 2. Therefore, in order to connect the through-hole wiring 4c to the second transmission line 4b, the first transmission line 4a is located on the first surface 2a of the first substrate 2 facing the second substrate 3.

Here, a direction in which the first transmission line 4a extends from the connection conductor 4d to the second transmission line 4b is defined as a first direction. The first direction is the X direction. A direction orthogonal to the first direction when viewed in the thickness direction of the first substrate 2 is defined as a second direction. The second direction is the Y direction. In the present embodiment, as illustrated in FIGS. 1 and 4, a size W1 of the first transmission line 4a is smaller than a size W2 of the connection conductor 4d in the second direction. Further, in the present embodiment, the size W1 of the first transmission line 4a is smaller than a size W3 of the through-hole wiring 4c in the second direction. It can be said that the size W1 of the first transmission line 4a in the second direction is a width of the first transmission line 4a. It can be said that the size W2 of the connection conductor 4d in the second direction is a diameter of the connection conductor 4d. It can be said that the size W3 of the through-hole wiring 4c in the second direction is a diameter of the through-hole wiring 4c.

In the present embodiment, as illustrated in FIG. 1, a size W4 of the second transmission line 4b is set to be the same as the size W1 of the first transmission line 4a in the second direction. It can be said that the size W4 of the second transmission line 4b in the second direction is a width of the second transmission line 4b.

In the present embodiment, the second transmission line 4b is connected to the first transmission line 4a connected to the through-hole wiring 4c instead of the through-hole wiring 4c. Therefore, the size W4 of the second transmission line 4b can be set not based on a size necessary as the connection conductor for connection with the through-hole wiring 4c, that is, the size W2 of the connection conductor 4d but based on the size W1 of the first transmission line 4a smaller than the size W2 of the connection conductor 4d. Therefore, the size W4 of the second transmission line 4b can be reduced. This means that an adjustment width of the size W4 of the second transmission line 4b increases. That is, in adjustment of the size W4 of the second transmission line 4b in consideration of characteristics of the transmission line 4 and the like, the size W4 of the second transmission line 4b is not limited to the size W2 of the connection conductor 4d or more, and can be made smaller than the size W2 of the connection conductor 4d. Thus, it is possible to easily adjust impedance of the transmission line 4.

### [1.1.2 Effects and Like]

The substrate connection structure 1 described above includes the first substrate 2, the second substrate 3 partially facing the first substrate 2 when viewed in the thickness direction of the first substrate 2, and the transmission line 4 extending over the first and second substrates 2 and 3. The transmission line 4 includes the first transmission line 4a on the first surface 2a facing the second substrate 3 in the first substrate 2, the second transmission line 4b on the second surface 3a facing the first substrate 2 in the second substrate 3, the through-hole wiring 4c at the position not overlapping the second transmission line 4b when viewed in the thickness direction of the first substrate 2, and the connection conductor 4d on the first surface 2a and connected to the through-hole wiring 4c. The first transmission line 4a extends from the connection conductor 4d to the second transmission line 4b and is connected to the second transmission line 4b. In the second direction (Y direction) orthogonal to the first direction (X direction) in which the first transmission line 4a extends from the connection conductor 4d to the second transmission line 4b when viewed in the thickness direction (Z direction) of the first substrate 2, the size W1 of the first transmission line 4a is smaller than the size W2 of the connection conductor 4d. This configuration enables easy adjustment of impedance of the transmission line 4.

In the substrate connection structure 1, the size W1 of the first transmission line 4a is smaller than the size W3 of the through-hole wiring 4c in the second direction. This configuration enables further easy adjustment of impedance of the transmission line 4.

In the substrate connection structure 1, the ends of the first and second substrates 2 and 3 face each other when viewed in the thickness direction of the first substrate 2. This configuration can increase the line length of the transmission line 4.

In the substrate connection structure 1, the through-hole wiring 4c is located at a position not overlapping the second substrate 3 when viewed in the thickness direction of the first substrate 2. This configuration enables a reduction in an influence of interference between the through-hole wiring 4c and the second substrate 3.

### 1.2 Second Embodiment

### [1.2.1 Configuration]

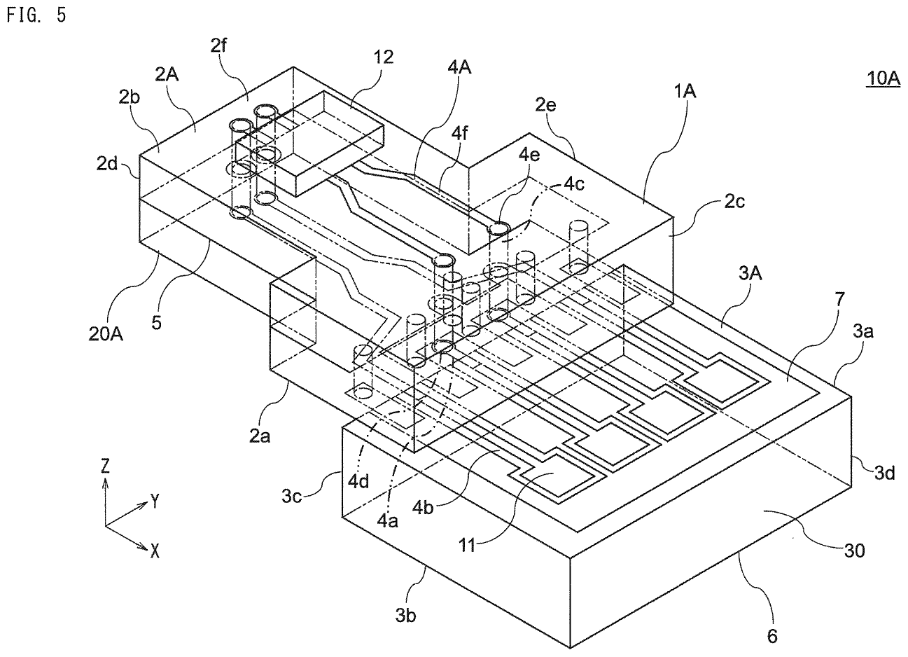

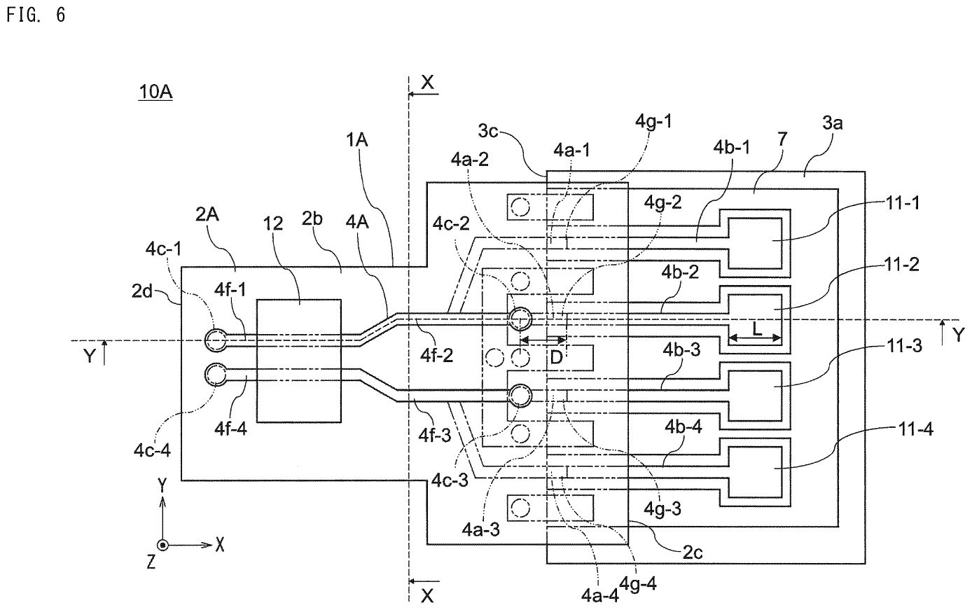

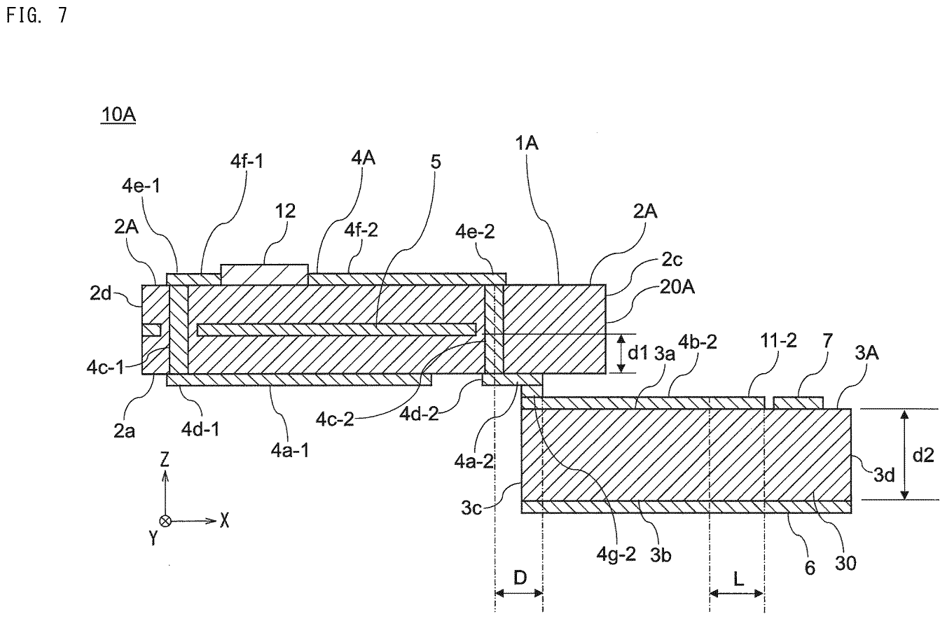

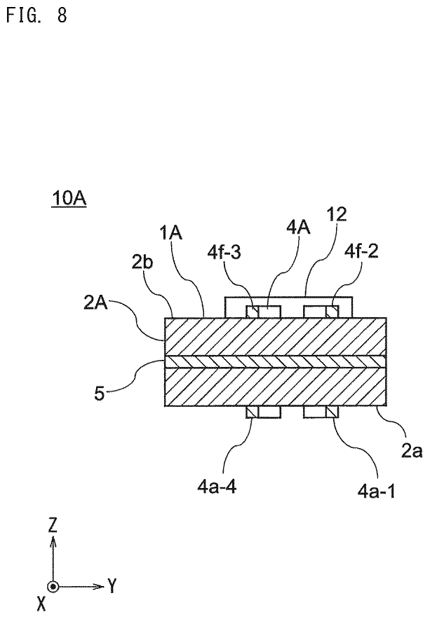

FIG. 5 is a perspective view of an antenna substrate 10A according to the second embodiment. FIG. 6 is a plan view of the antenna substrate 10A. FIG. 7 is a cross-sectional view taken along the line Y-Y of FIG. 6. FIG. 8 is a cross-sectional view taken along the line X-X of FIG. 6.

The antenna substrate 10A includes a substrate connection structure 1A, a plurality of radiation electrodes 11-1 to 11-4, and a processing circuit 12.

The substrate connection structure 1A includes a first substrate 2A, a second substrate 3A, and a transmission line 4A.

The first substrate 2A includes a dielectric layer 20A and a first grounding electrode 5.

The dielectric layer 20A has a multilayer structure, and the first grounding electrode 5 is disposed between the first and third surfaces 2a and 2b. Hereinafter, a wiring pattern formed on the third surface 2b is referred to as a wiring pattern of a first layer, the wiring pattern formed between the first and third surfaces 2a and 2b is referred to as a wiring pattern of a second layer, and the wiring pattern formed on the first surface 2a is referred to as a wiring pattern of a third layer.

The dielectric layer 20A has a shape in which the width of the first portion 2e on the first end 2c side is wider than the width of the second portion 2f on the second end 2d side.

The second substrate 3A includes a dielectric layer 30 and a second grounding electrode 6. The second grounding electrode 6 is located on the fourth surface 3b of the dielectric layer 30. The second grounding electrode 6 is located on a side of the second transmission line 4b opposite to the first substrate 2A. The second grounding electrode 6 is a conductor pattern. The second grounding electrode 6 has a planar shape. The second grounding electrode 6 has a substantially rectangular shape when viewed in the thickness direction (Z direction) of the second substrate 3A.

In the present embodiment, a dielectric constant of the second substrate 3A is lower than a dielectric constant of the first substrate 2A. A thickness of the second substrate 3A is greater than a thickness of the first substrate 2A.

As illustrated in FIG. 6, in the present embodiment, the first and second substrates 2A and 3A are also disposed to partially overlap each other when viewed in the thickness direction of first substrate 2A. The first surface 2a of the first substrate 2A partially faces the second surface 3a of the second substrate 3A. In particular, the end of the first surface 2a of the first substrate 2A on the first end 2c side faces the end of the second surface 3a of the second substrate 3A on the first end 3c side. Therefore, also in the present embodiment, the ends of the first and second substrates 2A and 3A face each other when viewed in the thickness direction of the first substrate 2A.

FIG. 6 is referred to. The radiation electrodes 11-1 to 11-4 are conductor patterns formed on the second surface 3a of the second substrate 3A. The radiation electrode 11 has a planar shape. In the present embodiment, a predetermined direction along a polarization direction of radio waves radiated from radiation electrode 11 is set to the X direction. The radiation electrode 11 has a substantially rectangular shape when viewed in the thickness direction (Z direction) of the second substrate 3A. The radiation electrodes 11-1 to 11-4 are arranged in a direction (Y direction) orthogonal to the direction (X direction) between the first end 3c and the second end 3d of the second substrate 3A when viewed in the thickness direction (Z direction) of the second substrate 3A.

The shape of the radiation electrodes 11-1 to 11-4 is determined according to a frequency band used for wireless communication. Examples of the frequency band of wireless communication include a frequency band around 28 GHz and a frequency band around 39 GHz.

In the present embodiment, the second grounding electrode 6 includes each grounding conductor included in a patch antenna together with the radiation electrodes 11-1 to 11-4. In the radiation electrode 11, a boundary portion between the radiation electrode 11 and the second transmission line 4b acts as a feeding point. In the present embodiment, a predetermined direction along the linear line connecting the feeding point and the center of radiation electrode 11 matches the X direction.

The processing circuit 12 is mounted on the third surface 2b of the first substrate 2A. The processing circuit 12 includes, for example, an IC. Examples of the processing circuit 12 include a system in package (SiP). The processing circuit 12 executes, for example, a process of performing wireless communication using the radiation electrodes 11-1 to 11-4. The processing circuit 12 can output high-frequency signals to the radiation electrodes 11-1 to 11-4 through the transmission line 4A. The processing circuit 12 can receive high-frequency signals from the radiation electrodes 11-1 to 11-4 through the transmission line 4A. The processing circuit 12 may be mounted together with the connector. In this case, the processing circuit 12 can transmit a signal through the connector.

The transmission line 4A extends over the first and second substrates 2A and 3A. In the present embodiment, the transmission line 4A is used for transmission of a high-frequency signal between the processing circuit 12 mounted on the third surface 2b of the first substrate 2A and the plurality of radiation electrodes 11 arranged on the second surface 3a of the second substrate 3A.

The transmission line 4A includes a plurality of first transmission lines 4a, a plurality of second transmission lines 4b, a plurality of through-hole wirings 4c, a plurality of connection conductors 4d, a plurality of connection conductors 4e, a plurality of third transmission lines 4f, and a plurality of connection layers 4g.

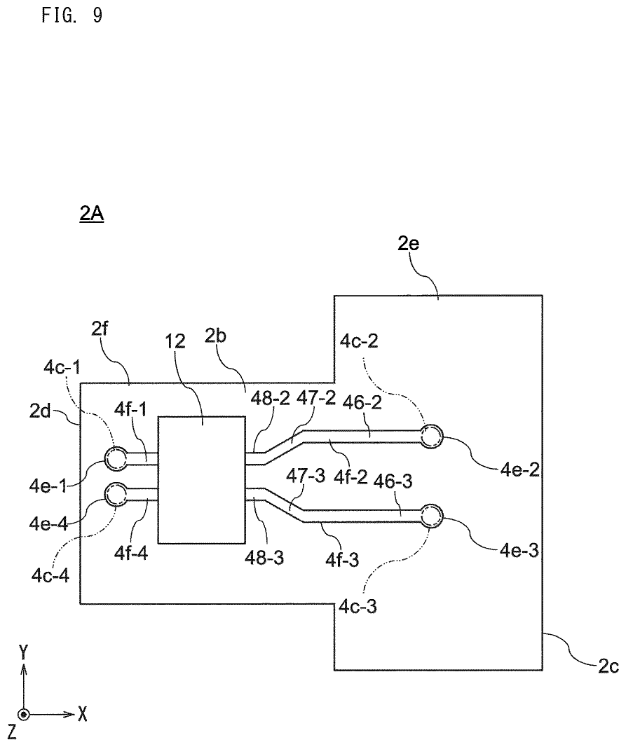

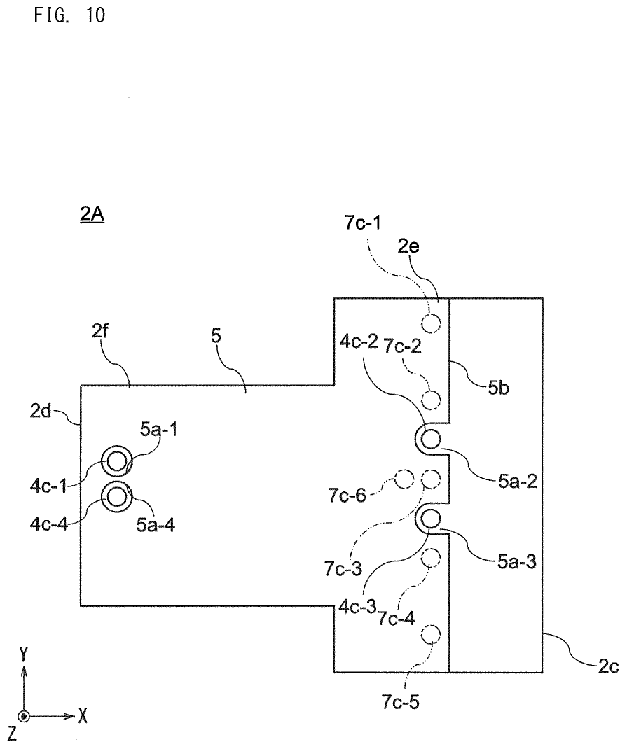

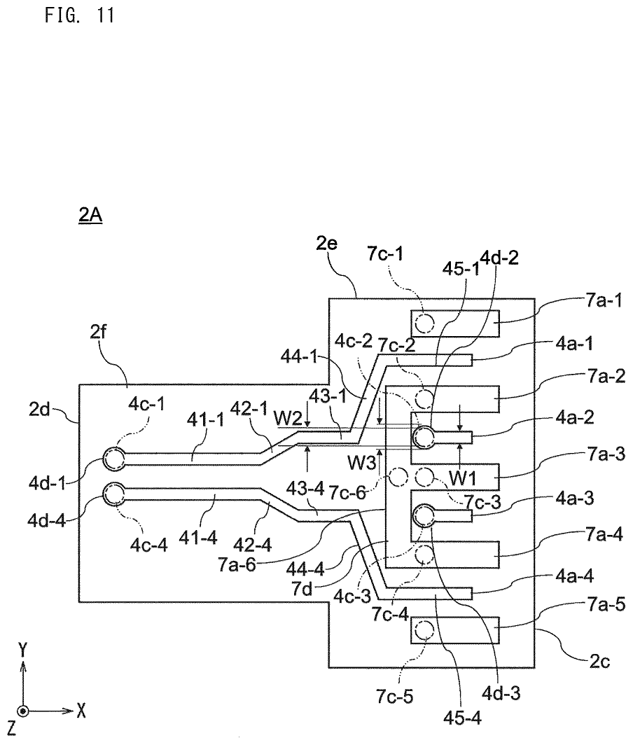

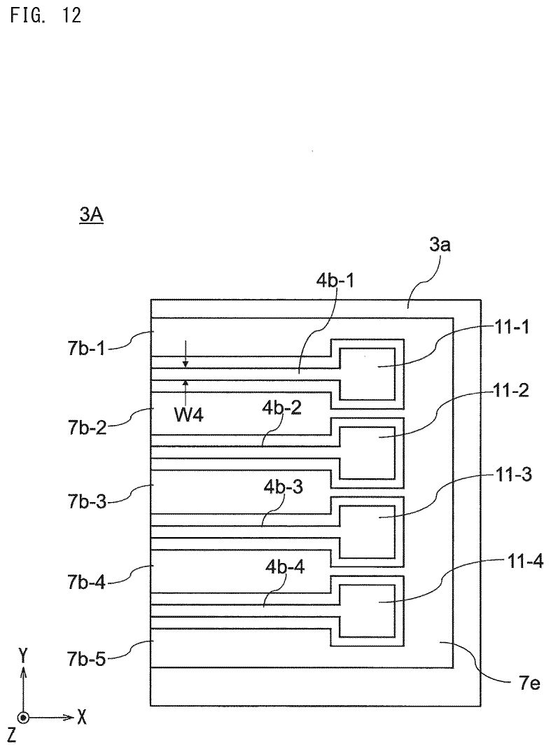

The transmission line 4A will be further described with reference to FIGS. 9 to 12 in addition to FIGS. 5 to 8. FIG. 9 is a plan view of a wiring pattern of a first layer of the first substrate 2A. FIG. 10 is a plan view of a wiring pattern of a second layer of the first substrate 2A. FIG. 11 is a plan view of a wiring pattern of a third layer of the first substrate 2A. FIG. 12 is a plan view of the second substrate 3A.

Referring to FIG. 12, second transmission lines 4b-1 to 4b-4 are located on the second surface 3a facing the first substrate 2A in the second substrate 3A. The second transmission lines 4b-1 to 4b-4 extend from the first end 3c of the second substrate 3 to the second end 3d. The second transmission lines 4b-1 to 4b-4 are arranged in a direction (Y direction) orthogonal to the direction (X direction) between the first end 3c and the second end 3d of the second substrate 3A when viewed in the thickness direction (Z direction) of the second substrate 3A, and are parallel to each other. An end portion of the second transmission lines 4b-1 to 4b-4 on the first end 3c side of the second substrate 3 is used as an electrode for connection with first transmission lines 4a-1 to 4a-4. The second transmission lines 4b-1 to 4b-4 are connected to the first transmission lines 4a-1 to 4a-4 at ends on the first end 3c side, and are connected to the radiation electrodes 11-1 to 11-4 at ends on the second end 3d side.

Referring to FIG. 5, the first transmission line 4a is located on the first surface 2a facing the second substrate 3A in the first substrate 2A, and the third transmission line 4f is located on the third surface 2b opposite to the second substrate 3A in the first substrate 2A. The through-hole wiring 4c and the connection conductors 4d and 4e connect the first and third transmission lines 4a and 4f on the first and third surfaces 2a and 2b different from each other.

Referring to FIGS. 9 to 11, through-hole wirings 4c-1 to 4c-4 penetrate through the first substrate 2A to be exposed to the first and third surfaces 2a and 2b of the first substrate 2A. The through-hole wirings 4c-2 and 4c-3 are located in the first portion 2e on the first end 2c side in the first substrate 2A, and the through-hole wirings 4c-1 and 4c-4 are located in the second portion 2f on the second end 2d side in the first substrate 2A. In the present embodiment, the through-hole wirings 4c-2 and 4c-3 are located on the opposite side to the through-hole wirings 4c-1 and 4c-4 with respect to the processing circuit 12. The through-hole wirings 4c-1 and 4c-4 are arranged in the Y direction, and the through-hole wirings 4c-2 and 4c-3 are arranged in the Y direction.

Referring to FIG. 11, the connection conductors 4d-1 to 4d-4 are connected to the through-hole wirings 4c-1 to 4c-4 on the first surface 2a of the first substrate 2A, respectively. Referring to FIG. 9, connection conductors 4e-1 to 4e-4 are connected to the through-hole wirings 4c-1 to 4c-4 on the third surface 2b of the first substrate 2A, respectively. More specifically, the connection conductors 4d-1 to 4d-4 and 4e-1 to 4e-4 are located at positions overlapping the through-hole wirings 4c-1 to 4c-4 when viewed in the thickness direction of the first substrate 2A.

Referring to FIG. 11, the first transmission lines 4a-1 to 4a-4 extend from the connection conductors 4d-1 to 4d-4 to the first end 2c side (the second transmission line 4b side) of the first substrate 2A, respectively. Ends of the first transmission lines 4a-1 to 4a-4 on the first end 2c side of the first substrate 2A are used as electrodes for connection with the second transmission lines 4b-1 to 4b-4. The first transmission lines 4a-1 to 4a-4 are connected to the second transmission lines 4b-1 to 4b-4 at the end on the first end 2c side, and are connected to the connection conductors 4d-1 to 4d-4 at the end on the second end 2d side.

The first transmission lines 4a-2 and 4a-3 have a linear shape in the X direction. Referring to FIGS. 6 and 7, the lengths of the first transmission line 4a-2 and the first transmission line 4a-3 are set to satisfy D<L. Here, L is a size of each of the radiation electrodes 11-2 and 11-3 in a predetermined direction along the polarization direction of radio waves emitted from the radiation electrodes 11-2 and 11-3. In the present embodiment, it can also be said that L is the size of each of the radiation electrodes 11-2 and 11-3 in a predetermined direction along a linear line connecting the feeding point to the center in radiation electrodes 11-2 and 11-3. D is a distance between the centers of the through-hole wirings 4c-2 and 4c-3 in the predetermined direction and the ends of the first transmission lines 4a-2 and 4a-3 on the second transmission lines 4b-2 and 4b-3 side. When D-L is satisfied, there is a possibility of radio wave radiation occurring in the first transmission line 4a-2 and the first transmission line 4a-3, that is, the first transmission lines 4a-2 and 4a-3 is likely to function as antennas instead of the radiation electrodes 11-2 and 11-3. By satisfying D<L, a possibility of unnecessary radio wave radiation occurring in the first transmission lines 4a-2 and 4a-3 can be reduced. This enables improvement of antenna efficiency of the antenna substrate 10A.

The first transmission lines 4a-1 and 4a-4 have a bent shape. The first transmission lines 4a-1 and 4a-4 include first to fifth lines 41-1 to 45-1 and 41-4 to 45-4. The first lines 41-1 and 41-4 extend in the X direction from the connection conductors 4d-1 to 4d-4. The second lines 42-1 and 42-4 extend in directions away from the ends of the first lines 41-1 and 41-4 on the first end 2c side. The third lines 43-1 and 43-4 extend in the X direction from the ends of the second lines 42-1 and 42-4 on the first end 2c side. The third lines 43-1 and 43-4 are arranged in a linear line with the first transmission lines 4a-2 and 4a-3, respectively, in the X direction. The fourth lines 44-1 and 44-4 extend in directions away from the ends of the third lines 43-1 and 43-4 on the first end 2c side. The fifth lines 45-1 and 45-4 extend in the X direction from the ends of the fourth lines 44-1 and 44-4 on the first end 2c side. The fifth lines 45-1 and 45-4 are located on both sides of the first transmission lines 4a-2 and 4a-3 in the Y direction. Accordingly, the fifth line 45-1, the first transmission line 4a-2, the first transmission line 4a-3, and the fifth line 45-4 are arranged in the Y direction.

Referring to FIG. 9, the third transmission lines 4f-1 and 4f-4 extend from the connection conductors 4e-1 and 4e-4 to the first end 2c side (the second transmission line 4b side) of the first substrate 2A, respectively. The third transmission lines 4f-1 and 4f-4 have a linear shape in the X direction. The third transmission lines 4f-1 and 4f-4 are respectively connected to the connection conductors 4e-1 and 4e-4 at ends on the first end 2c side, and are connected to the processing circuit 12 at ends on the second end 2d side.

The third transmission lines 4f-2 and 4f-3 extend from the connection conductors 4e-2 and 4e-3 to the second end 2d side of the first substrate 2A (the side opposite to the second transmission line 4b), respectively. The third transmission lines 4f-2 and 4f-3 have a bent shape. The third transmission lines 4f-2 and 4f-3 include sixth to eighth lines 46-2 to 48-2 and 46-3 to 48-3. The sixth lines 46-3 and 46-2 extend in the X direction from the connection conductors 4e-2 to 4e-3. The sixth lines 46-2 and 46-3 partially overlap the third lines 43-1 and 43-4 when viewed in the thickness direction of the first substrate 2A. The seventh lines 47-2 and 47-3 extend in directions approaching each other from ends of the sixth lines 46-2 and 46-3 on the second end 2d side. The seventh lines 47-2 and 47-3 overlap the second lines 42-1 and 42-4 when viewed in the thickness direction of the first substrate 2A. The eighth lines 48-2 and 48-3 extend in the X direction from the ends on the second end 2d side of the seventh lines 47-2 and 47-3 and are connected to the processing circuit 12. The eighth lines 48-2 and 48-3 partially overlap the first lines 41-1 and 41-4 when viewed in the thickness direction of the first substrate 2A. The eighth lines 48-2 and 48-3 are arranged with the third transmission lines 4f-1 and 4f-4 in a linear line in the X direction.

Referring to FIG. 6, connection layers 4g-1 to 4g-4 are arranged between the first transmission lines 4a-1 to 4a-4 and the second transmission lines 4b-1 to 4b-4, respectively, and couple the first transmission lines 4a-1 to 4a-4 and the second transmission lines 4b-1 to 4b-4, respectively.

Referring to FIGS. 7 and 8 together, the third transmission line 4f-2 is a parallel running line that is separated from the first first transmission line 4a-1 among the plurality of first first transmission lines 4a-1 to 4a-4 in the thickness direction of the first substrate 2A, and is connected to the second first transmission line 4a-2 different from the first first transmission line 4a-1 among the plurality of first transmission lines 4a-1 to 4a-4 via the through-hole wiring 4c-2. In particular, the third transmission line 4f-2 partially overlaps the first transmission line 4a-1 in the thickness direction of the first substrate 2A. The first first transmission line 4a-1 and the second first transmission line 4a-2 are connected to two adjacent second transmission lines 4b-1 and 4b-2 among the plurality of second transmission lines 4b-1 to 4b-4.

Similarly, the third transmission line 4f-3 is a parallel running line that is separated from the first first transmission line 4a-4 among the plurality of first transmission lines 4a-1 to 4a-4 in the thickness direction of the first substrate 2A, and is connected to the second first transmission line 4a-3 different from the first first transmission line 4a-4 among the plurality of first transmission lines 4a-1 to 4a-4 via the through-hole wiring 4c-3. In particular, the third transmission line 4f-3 partially overlaps the first transmission line 4a-4 in the thickness direction of the first substrate 2A. The first first transmission line 4a-4 and the second first transmission line 4a-3 are connected to two adjacent second transmission lines 4b-3 and 4b-4 among the plurality of second transmission lines 4b-1 to 4b-4.

The first substrate 2A includes the first grounding electrode 5, and at least a part of the first grounding electrode 5 is between the third and first transmission lines 4f-2 and 4a-1 and between the third and first transmission lines 4f-3 and 4a-4. That is, when viewed in the thickness direction of the first substrate 2A, at least a part of the first grounding electrode 5, at least a part of the first transmission line 4a-1, and at least a part of the third transmission line 4f-2 overlap each other. At least a part of the first grounding electrode 5, at least a part of the first transmission line 4a-4, and at least a part of the third transmission line 4f-3 overlap each other. Therefore, it is possible to improve isolation between the third and first transmission lines 4f-2 and 4a-1 and between the third and first transmission lines 4f-3 and 4a-4. As described above, in the substrate connection structure 1A, the first first transmission lines (the first transmission lines 4a-1 and 4a-4) and the parallel running lines (the third transmission lines 4f-2 and 4f-3) connected to the second first transmission lines (4a-2 and 4a-3) can be arranged separately in the thickness direction of the first substrate 2A. Accordingly, the plurality of first transmission lines 4a-1 to 4a-4 can be efficiently arranged using the thickness direction of the first substrate 2A, and a range in which the plurality of first transmission lines 4a-1 to 4a-4 are arranged on the first surface 2a can be narrowed. Thus, the area required for arranging the plurality of first transmission lines 4a-1 to 4a-4 on the first substrate 2A can be reduced.

Further, the first first transmission line 4a-1 and the second first transmission line 4a-2 are connected to two adjacent second transmission lines 4b-1 and 4b-2 among the plurality of second transmission lines 4b-1 to 4b-4. The first first transmission line 4a-4 and the second first transmission line 4a-3 are connected to two adjacent second transmission lines 4b-3 and 4b-4 among the plurality of second transmission lines 4b-1 to 4b-4. Therefore, the second transmission lines 4b-1 to 4b-4 can be arranged on the same plane (second surface 3a) while reducing an area required to arrange the plurality of first transmission lines 4a-1 to 4a-4 on the first substrate 2A.

The first grounding electrode 5 will be further described with reference to FIG. 10. The first grounding electrode 5 is located between the first and third surfaces 2a and 2b in the dielectric layer 20A of the first substrate 2A. The first grounding electrode 5 is disposed between the third and first transmission lines 4f-2 and 4a-1 and between the third and first transmission lines 4f-3 and 4a-4. The first grounding electrode 5 has voids 5a-1 to 5a-4 so as not to be in contact with the through-hole wirings 4c-1 to 4c-4. Referring to FIG. 11, the first grounding electrode 5 has a side 5b on the first end 2c side of the first substrate 2A. The side 5b of the first grounding electrode 5 is separated from the first end 2c by a predetermined distance. Here, the predetermined distance is set such that the first grounding electrode 5 does not overlap the second substrate 3A when viewed in the thickness direction of the first substrate 2A.

The first grounding electrode 5 can affect impedance in the first transmission lines 4a-2 and 4a-3. Since the first transmission lines 4a-2 and 4a-3 have the same structure, the first transmission line 4a-2 will be referred to below for brevity of description.

The impedance at the first transmission line 4a-2 increases as capacitance between the first transmission line 4a-2 and the first grounding electrode 5 decreases. When C1 is a capacitance between the first transmission line 4a-2 and the first grounding electrode 5, C1=ε1*S1/d1 is established. E1 is a dielectric constant of the first substrate 2A. The dielectric constant of the first substrate 2A is the dielectric constant of the dielectric layer 20A of the first substrate 2A. S1 is an area of an overlapping portion between the first transmission line 4a-2 and the first grounding electrode 5 when viewed in the thickness direction of the first substrate 2A. d1 is a distance between the first transmission line 4a-2 and the first grounding electrode 5 in the thickness direction of the first substrate 2A as illustrated in FIG. 7.

As the impedance at the first transmission line 4a-2 is closer to the impedance at the second transmission line 4b-2 to which the first transmission line 4a-2 is connected, reflection or the like can be reduced to improve transmission efficiency. The impedance at the second transmission line 4b-2 is affected by the capacitance between the second transmission line 4b-2 and the second grounding electrode 6, and decreases as the capacitance increases. When C2 is a capacitance between the second transmission line 4b-2 and the second grounding electrode 6, C2=ε2*S2/d2 is established. ε2 is a dielectric constant of the second substrate 3A. The dielectric constant of the second substrate 3A is a dielectric constant of the dielectric layer 30 of the second substrate 3A. S2 is an area of an overlapping portion between the second transmission line 4b-2 and the second grounding electrode 6 when viewed in the thickness direction of the second substrate 3A. d2 is a distance between the second transmission line 4b-2 and the second grounding electrode 6 in the thickness direction of the second substrate 3A as illustrated in FIG. 7.

In the present embodiment, the dielectric constant ε1 of the first substrate 2A is higher than the dielectric constant ε2 of the second substrate 3A, and the distance d1 is shorter than the distance d2. In this case, C1 tends to be larger than C2. Therefore, S1 is reduced so that C1 is reduced. Therefore, in the present embodiment, the first grounding electrode 5 is configured not to overlap second substrate 3A when viewed in the thickness direction of first substrate 2A. Accordingly, a difference between the impedance in the first transmission line 4a-2 and the impedance in the second transmission line 4b-2 can be reduced, and transmission efficiency of the transmission line 4A can be improved.

In the substrate connection structure 1A of the antenna substrate 10A described above, as illustrated in FIG. 6, the through-hole wirings 4c-1 to 4c-4 are located at positions not overlapping the second transmission lines 4b-1 to 4b-4 when viewed in the thickness direction of the first substrate 2A. In particular, the through-hole wirings 4c-1 to 4c-4 are located at positions not overlapping the second substrate 3A when viewed in the thickness direction of the first substrate 2A. Therefore, in order to connect the through-hole wirings 4c-1 to 4c-4 to the second transmission lines 4b-1 to 4b-4, respectively, the first transmission lines 4a-1 to 4a-4 are located on the first surface 2a facing the second substrate 3A in the first substrate 2A.

Referring to FIG. 11, in the second direction (Y direction), the size W1 of the first transmission line 4a-2 is smaller than the size W2 of the connection conductor 4d-2. Further, in the second direction, the size W1 of the first transmission line 4a-2 is smaller than the size W3 of the through-hole wiring 4c-2. This similarly applies to the first transmission lines 4a-1, 4a-3, and 4a-4. Here, the first transmission line 4a-1 has a bent shape, but includes a linear first line 41-1 extending from the connection conductor 4d-1. The size W2 of the first transmission line 4a-1 in the second direction (Y direction) may be the size of the first line 41-1 in the second direction (Y direction), and the sizes of the second to fifth lines 42-1 to 45-1 in the second direction are set based on the size of the first line 41-1 in the second direction. This point also applies to the first transmission line 4a-4.

The second transmission line 4b is connected to the first transmission line 4a connected to the through-hole wiring 4c instead of the through-hole wiring 4c. Therefore, the size W4 (see FIG. 12) of the second transmission line 4b can be set not based on a size necessary as the connection conductor for connection with the through-hole wiring 4c, that is, the size W2 of the connection conductor 4d, but based on the size W1 of the first transmission line 4a smaller than the size W2 of the connection conductor 4d. Accordingly, the substrate connection structure 1A enables easy adjustment of the impedance of the transmission line 4A.

In the substrate connection structure 1A, the plurality of second transmission lines 4b are arranged in the second direction and are parallel to each other. As described above, the size W4 of the second transmission line 4b can be set based on the size W1 of the first transmission line 4a smaller than the size W2 of the connection conductor 4d. Therefore, even when the intervals between the plurality of second transmission lines 4b are the same, the size W4 of the second transmission line 4b can be reduced. Therefore, a gap between the adjacent second transmission lines 4b can be increased. Accordingly, the substrate connection structure 1A enables easy adjustment of the impedance of the transmission line 4A even when there are the plurality of second transmission lines 4b.

Referring to FIG. 5, the transmission line 4A includes a grounding structure 7. Referring to FIGS. 11 and 12 together, the grounding structure 7 includes grounding lines 7a-1 to 7a-5 and 7b-1 to 7b-5, through-hole wirings 7c-1 to 7c-6, and connection lines 7d and 7e.

Referring to FIG. 11, the grounding lines 7a-1 to 7a-5 and the connection line 7d are located on the first surface 2a of the first substrate 2A. The grounding lines 7a-1 to 7a-5 have a linear shape extending in the X direction and are arranged in the Y direction. The grounding lines 7a-1 to 7a-5 are arranged such that two of the grounding lines 7a-1 to 7a-5 are located on both sides of one of the first transmission lines 4a-1 to 4a-4 in the second direction (Y direction). The first transmission line 4a-1 is located between the grounding lines 7a-1 and 7a-2. The first transmission line 4a-2 is located between the grounding lines 7a-2 and 7a-3. The first transmission line 4a-3 is located between the grounding lines 7a-3 and 7a-4. The first transmission line 4a-4 is located between the grounding lines 7a-4 and 7a-5.

The connection line 7d connects the ends of the grounding lines 7a-2 to 7a-4 on the second end 2d side of the first substrate 2A. The connection line 7d is located between the first transmission lines 4a-1 and 4a-2 and between the first transmission lines 4a-3 and 4a-4 in the X direction, which improves isolation therebetween.

The through-hole wirings 7c-1 to 7c-6 are located in the first substrate 2A. The through-hole wirings 7c-1 to 7c-6 are via hole wirings penetrating through portions between the first surface 2a and the first grounding electrode 5 in the dielectric layer 20A to connect the grounding lines 7a-1 to 7a-5 and the connection line 7d to the first grounding electrode 5.

Referring to FIG. 12, the grounding lines 7b-1 to 7b-5 and the connection line 7e are located on the second surface 3a of the second substrate 3A. The grounding lines 7b-1 to 7b-5 have a linear shape extending in the X direction and are arranged in the Y direction. The grounding lines 7b-1 to 7b-5 are arranged such that two of the grounding lines 7b-1 to 7b-5 are located on both sides of one of the second transmission lines 4b-1 to 4b-4 in the second direction (Y direction). The second transmission line 4b-1 and the radiation electrode 11-1 are located between the grounding lines 7b-1 and 7b-2. The second transmission line 4b-2 and the radiation electrode 11-2 are located between the grounding lines 7b-2 and 7b-3. The second transmission line 4b-3 and the radiation electrode 11-3 are located between the grounding lines 7b-3 and 7b-4. The second transmission line 4b-4 is located between the grounding lines 7b-4 and 7b-5.

The connection line 7e connects the ends of the grounding lines 7b-1 to 7b-5 on the second end 3d side of the second substrate 3A. The connection line 7e and the grounding lines 7b-1 and 7b-5 surround the second transmission lines 4b-1 to 4b-4 and the radiation electrodes 11-1 to 11-4.

In the grounding structure 7, the ends of the grounding lines 7a-1 to 7a-5 on the first end 2c side of the first substrate 2A are connected to the ends of the grounding lines 7b-1 to 7b-5 on the first end 3c side of the second substrate 3A by a conductive connection material such as solder.

The transmission line 4A includes the grounding structure 7, and thus includes the grounding line 7a on both sides of the first transmission line 4a and the grounding line 7b on both sides of the second transmission line 4b in the second direction. The first transmission line 4a and the grounding lines 7a on both sides of the first transmission line 4a, and the second transmission line 4b and the grounding line 7b on both sides of the second transmission line 4b each form a coplanar line. In this way, by configuring these lines as the coplanar line, suppression of unnecessary radiation and improvement of resistance to disturbance are realized as compared with a microstrip line. That is, this configuration enables reduction of unnecessary radiation and improvement of resistance to disturbance.

As described above, the size W1 of the first transmission line 4a is smaller than the size W2 of the connection conductor 4d. Therefore, even when the intervals between the plurality of first transmission lines 4a are the same, the size W1 of the first transmission line 4a can be reduced. Therefore, a gap between the adjacent first transmission lines 4a can be increased. Therefore, the width of the grounding line 7a (the size of the grounding line 7a in the second direction) can be increased without changing the distance between the grounding line 7a and the first transmission line 4a. Accordingly, it is possible to improve isolation characteristics between the adjacent first transmission lines 4a.

Further, the size W4 of the second transmission line 4b can be set based on the size W1 of the first transmission line 4a smaller than the size W2 of the connection conductor 4d. Therefore, even when the intervals between the plurality of second transmission lines 4b are the same, the size W4 of the second transmission line 4b can be reduced. Therefore, a gap between the adjacent second transmission lines 4b can be increased. Therefore, the width of the grounding line 7b (the size of the grounding line 7b in the second direction) can be increased without changing the distance between the grounding line 7b and the second transmission line 4b. Accordingly, it is possible to improve isolation characteristics between the adjacent second transmission lines 4b.

### [1.2.2 Effects and Like]

In the substrate connection structure 1A described above, the transmission line 4A includes the plurality of second transmission lines 4b. Two or more of the plurality of second transmission lines 4b are parallel to each other. In this configuration, since the size W4 of the second transmission line 4b can be reduced, the gap between the adjacent second transmission lines 4b can be increased. Accordingly, the substrate connection structure 1A enables easy adjustment of the impedance of the transmission line 4A even when there are the plurality of second transmission lines 4b.

In the substrate connection structure 1A, the transmission line 4A includes the plurality of first transmission lines 4a-1 to 4a-4. The transmission line 4A includes the third transmission line 4f-2 that is a parallel running line separated from the first first transmission line 4a-1 among the plurality of first transmission lines 4a-1 to 4a-4 in the thickness direction of the first substrate 2A and connected to the second first transmission line 4a-2 different from the first first transmission line 4a-1 among the plurality of first transmission lines 4a-1 to 4a-4 via the through-hole wiring 4c-2. The first substrate 2A includes the first grounding electrode 5. At least a part of the first grounding electrode 5 is located between the first first transmission line (the first transmission line 4a-1) and the parallel running line (the third transmission line 4f-2) in the thickness direction of the first substrate 2A. In this configuration, it is possible to reduce an area required for arranging the plurality of first transmission lines 4a-1 to 4a-4 on the first substrate 2A.

In the substrate connection structure 1A, the transmission line 4A includes the plurality of first transmission lines 4a-1 to 4a-4. The transmission line 4A includes the third transmission line 4f-2 that is a parallel running line separated from the first first transmission line 4a-1 among the plurality of first transmission lines 4a-1 to 4a-4 in the thickness direction of the first substrate 2A and connected to the second first transmission line 4a-2 different from the first first transmission line 4a-1 among the plurality of first transmission lines 4a-1 to 4a-4 via the through-hole wiring 4c-2. The first substrate 2A includes the first grounding electrode 5. When viewed in the thickness direction of the first substrate 2A, at least a part of the first grounding electrode 5, at least a part of the first first transmission line (first transmission line 4a-1), and at least a part of the parallel running line (third transmission line 4f-2) overlap each other. In this configuration, it is possible to reduce an area required for arranging the plurality of first transmission lines 4a-1 to 4a-4 on the first substrate 2A.

In the substrate connection structure 1A, the transmission line 4A includes the plurality of second transmission lines 4b-1 to 4b-4. The first first transmission line 4a-1 and the second first transmission line 4a-2 are connected to two adjacent second transmission lines 4b-1 and 4b-2 among the plurality of second transmission lines 4b-1 to 4b-4, and the first first transmission line 4a-4 and the second first transmission line 4a-3 are connected to two adjacent second transmission lines 4b-3 and 4b-4 among the plurality of second transmission lines 4b-1 to 4b-4. Therefore, the second transmission lines 4b-1 to 4b-4 can be arranged on the same plane (second surface 3a) while reducing an area required to arrange the plurality of first transmission lines 4a-1 to 4a-4 on the first substrate 2A.

In the substrate connection structure 1A, the dielectric constant of the first substrate 2A is higher than the dielectric constant of the second substrate 3A. A distance d1 between the first transmission lines 4a-2 and 4a-3 and the first grounding electrode 5 in the thickness direction of the first substrate 2A is shorter than a distance d2 between the second transmission lines 4b-2 and 4b-3 and the second grounding electrode 6 on the opposite side of the first substrate 2A with respect to the second transmission lines 4b-2 and 4b-3 in the thickness direction of the second substrate 3A. When viewed in the thickness direction of the first substrate 2A, the first grounding electrode 5 does not overlap the second substrate 3A. In this configuration, it is possible to reduce a difference between the impedance in the first transmission lines 4a-2 and 4a-3 and the impedance in the second transmission lines 4b-2 and 4b-3, and improve transmission efficiency of the transmission line 4A.

In the substrate connection structure 1A, the transmission line 4A includes the grounding line 7a on both sides of the first transmission line 4a and the grounding line 7b on both sides of the second transmission line 4b in the second direction. The first transmission line 4a and the grounding lines 7a on both sides of the first transmission line 4a, and the second transmission line 4b and the grounding line 7b on both sides of the second transmission line 4b each form a coplanar line. In this way, by configuring these lines as the coplanar line, suppression of unnecessary radiation and improvement of resistance to disturbance are realized as compared with a microstrip line. That is, this configuration enables reduction of unnecessary radiation and improvement of resistance to disturbance.

The antenna substrate 10A described above includes the substrate connection structure 1A and the radiation electrode 11 located on the second substrate 3A and connected to the second transmission line 4b. This configuration enables easy adjustment of the impedance of the transmission line 4A.

The antenna substrate 10A satisfies D<L. L is a size of the radiation electrodes 11-2 and 11-3 in the predetermined direction along the polarization direction of the radio waves emitted from the radiation electrodes 11-2 and 11-3. D is a distance between the centers of the through-hole wirings 4c-2 and 4c-3 in the predetermined direction and the ends of the first transmission lines 4a-2 and 4a-3 on the second transmission lines 4b-2 and 4b-3 side. In this configuration, it is possible to reduce a possibility of unnecessary radio wave radiation occurring in the first transmission lines 4a-2 and 4a-3, and improve the antenna efficiency of the antenna substrate 10A.

From another point of view, the antenna substrate 10A satisfies D<L. In this case, L is a size of radiation electrodes 11-2 and 11-3 in a predetermined direction along a linear line connecting the feeding point and the center of radiation electrodes 11-2 and 11-3. D is a distance between the centers of the through-hole wirings 4c-2 and 4c-3 in the predetermined direction and the ends of the first transmission lines 4a-2 and 4a-3 on the second transmission lines 4b-2 and 4b-3 side. In this configuration, it is possible to reduce a possibility of unnecessary radio wave radiation occurring in the first transmission lines 4a-2 and 4a-3, and improve the antenna efficiency of the antenna substrate 10A.

### 1.3 Third Embodiment

### [1.3.1 Configuration]

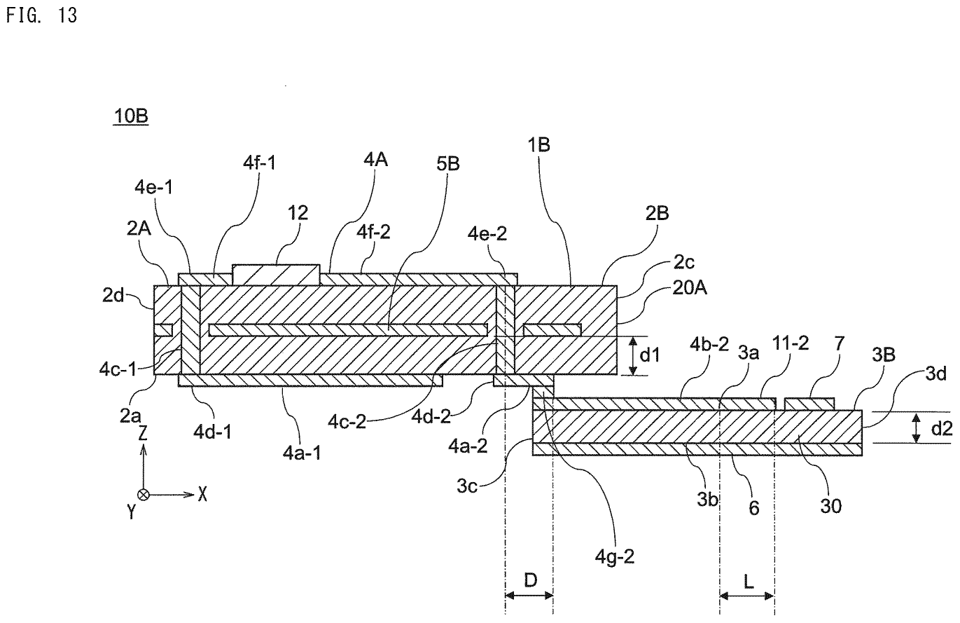

FIG. 13 is a cross-sectional view of an antenna substrate 10B according to a third embodiment. The antenna substrate 10B includes a substrate connection structure 1B, a plurality of radiation electrodes 11-1 to 11-4, and a processing circuit 12.

The substrate connection structure 1B includes a first substrate 2B, a second substrate 3B, and a transmission line 4A.

The second substrate 3B is different from the second substrate 3A in dielectric constant and thickness. The dielectric constant of the second substrate 3B is higher than the dielectric constant of the first substrate 2B. The thickness of the second substrate 3B is thinner than the thickness of the first substrate 2B.

The first substrate 2B includes a dielectric layer 20A and a first grounding electrode 5B.

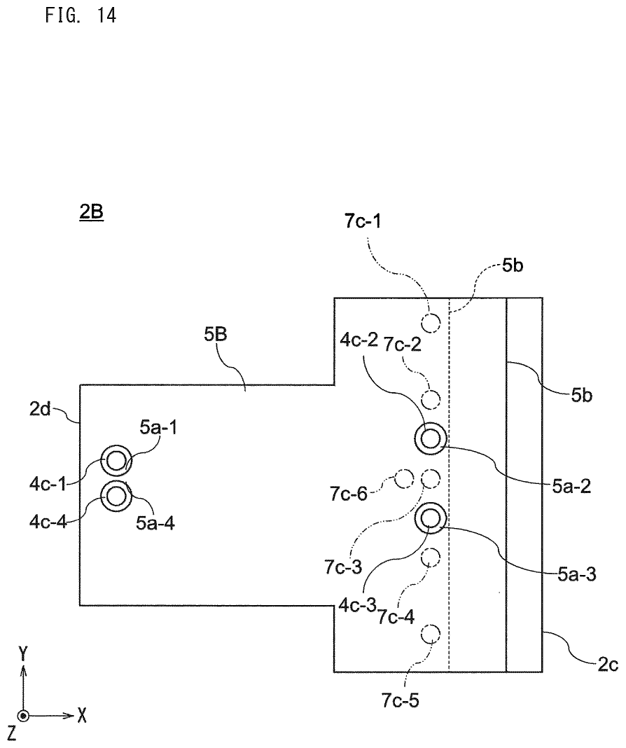

FIG. 14 is a plan view of a wiring pattern of a second layer of the first substrate 2B. In the first grounding electrode 5B, the side 5b of the first substrate 2A on the first end 2c side is closer to the first end 2c side than the first grounding electrode 5. In FIG. 14, the side 5b of the first grounding electrode 5B is indicated by a solid line, and the side 5b of the first grounding electrode 5 is indicated by a broken line. In the first grounding electrode 5B, a predetermined distance between the side 5b and the first end 2c is set such that at least a part of the first grounding electrode 5B overlaps the second substrate 3B when viewed in the thickness direction of the first substrate 2A.

In the present embodiment, the dielectric constant ε1 of the first substrate 2B is lower than the dielectric constant ε2 of the second substrate 3B, and the distance d1 is longer than the distance d2. In this case, C1 tends to be smaller than C2. Therefore, S1 is increased to increase C1. Therefore, in the present embodiment, at least a part of the first grounding electrode 5B is configured to overlap the second substrate 3B when viewed in the thickness direction of the first substrate 2B. Accordingly, a difference between the impedance in the first transmission line 4a-2 and the impedance in the second transmission line 4b-2 can be reduced, and transmission efficiency of the transmission line 4A can be improved.

### [1.3.2 Effects and Like]

In the substrate connection structure 1B described above, the dielectric constant of the first substrate 2B is lower than the dielectric constant of the second substrate 3B. The distance d1 between the first transmission lines 4a-2 and 4a-3 and the first grounding electrode 5B in the thickness direction of the first substrate 2B is longer than the distance d2 between the second transmission lines 4b-2 and 4b-3 and the second grounding electrode 6 on the opposite side of the first substrate 2B with respect to the second transmission lines 4b-2 and 4b-3 in the thickness direction of the second substrate 3B. When viewed in the thickness direction of the first substrate 2B, at least a part of the first grounding electrode 5B overlaps the second substrate 3B. In this configuration, it is possible to reduce a difference between the impedance in the first transmission lines 4a-2 and 4a-3 and the impedance in the second transmission lines 4b-2 and 4b-3, and improve transmission efficiency of the transmission line 4A.

### 1.4 Fourth Embodiment

### [1.4.1 Configuration]

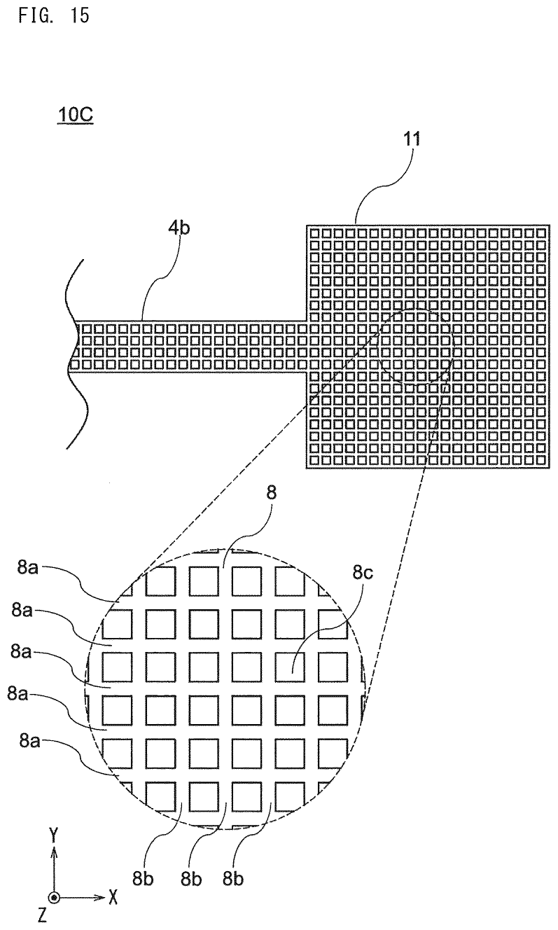

FIG. 15 is a plan view of a second transmission line 4b and a radiation electrode 11 of an antenna substrate 10C according to a fourth embodiment. The antenna substrate 10C according to the fourth embodiment includes a substrate connection structure 1B, a plurality of radiation electrodes 11-1 to 11-4, and a processing circuit 12 similarly to the antenna substrate 10B according to the third embodiment. The substrate connection structure 1B includes a first substrate 2B, a second substrate 3B, and a transmission line 4A. The antenna substrate 10C is different from the antenna substrate 10B in that second transmission line 4b, the radiation electrode 11, a second grounding electrode 6, and a grounding structure 7 have a mesh structure 8.

The mesh structure 8 includes a plurality of first linear conductors 8a and a plurality of second linear conductors 8b intersecting the plurality of first linear conductors 8a. The plurality of first linear conductors 8a are parallel to each other. The plurality of first linear conductors 8a extend in the third direction. The plurality of second linear conductors 8b are parallel to each other. The plurality of second linear conductors 8b extend in a fourth direction different from the third direction. In the present embodiment, the third direction corresponds to the length direction (X direction) of the second transmission line 4b. The fourth direction does not correspond to the length direction (X direction) of the second transmission line 4b but corresponds to the direction (Y direction) orthogonal to the third direction.

In the mesh structure 8, the adjacent first linear conductors 8a and the adjacent second linear conductors 8b define one opening 8c. The plurality of openings 8c are regularly arranged in the third and fourth directions. Due to presence of the plurality of openings 8c, visibility of the mesh structure 8 itself is reduced. That is, it is difficult to see the mesh structure 8 with the naked eye. As an example, a width of the first linear conductor 8a and a width of the second linear conductor 8b are 1 μm, and an interval between the first linear conductors 8a and an interval between the second linear conductors 8b are 100 μm. A ratio of a total area of the plurality of openings 8c to an area of a region where the mesh structure 8 is disposed is preferably 80% or more. Transmittance of visible light of the mesh structure 8 is preferably 80% or more.

The second transmission line 4b has the mesh structure 8. Therefore, the visibility of the second transmission line 4b can be reduced. In the mesh structure 8, the third direction corresponds to a length direction (X direction) of the second transmission line 4b. Therefore, as compared with a case where the third direction does not correspond to the length direction of the second transmission line 4b, a path of a current flowing through the second transmission line 4b can be shortened, a loss of the current in the second transmission line 4b can be reduced, and an antenna gain can be improved.

When the second transmission line 4b has the mesh structure 8, an electric field is easily transmitted to the outside in the fourth direction (Y direction). Therefore, the isolation characteristics are likely to deteriorate as compared with a case where the second transmission line 4b does not have the mesh structure 8. However, as described above, the size W4 of the second transmission line 4b can be set based on the size W1 of the first transmission line 4a smaller than the size W2 of the connection conductor 4d. Here, when d is an interval between the plurality of second transmission lines 4b and I is a gap between the adjacent second transmission lines 4b, d=W4+I is satisfied. Therefore, when the size W4 of the second transmission line 4b can be reduced, the gap I between the adjacent second transmission lines 4b can be increased without changing the interval d between the plurality of second transmission lines 4b. Therefore, even when the isolation characteristics deteriorate due to the mesh structure 8, the isolation characteristics can be improved as a whole. On the other hand, since the interval d between the plurality of second transmission lines 4b can be narrowed without changing the gap I between the adjacent second transmission lines 4b, an area required for mounting the plurality of second transmission lines 4b can be reduced with the isolation characteristics maintained. Thus, a substrate area of the second substrate 3B can be reduced.

The radiation electrode 11 has the mesh structure 8. Therefore, visibility of the radiation electrode 11 can be reduced. The radiation electrode 11 has the same mesh structure 8 as the second transmission line 4b. Here, in the mesh structure 8 of the second transmission line 4b and the mesh structure 8 of the radiation electrode 11, when the third directions match each other and the fourth directions match each other, it can be said that the second transmission line 4b and the radiation electrode 11 have the same mesh structure 8. That is, in the mesh structure 8 of the second transmission line 4b and the mesh structure 8 of the radiation electrode 11, a width of the first linear conductor 8a, a width of the second linear conductor 8b, an interval between the first linear conductors 8a, and an interval between the second linear conductors 8b may not match each other. Since the second transmission line 4b and the radiation electrode 11 have the same mesh structure 8, a current efficiently flows between the second transmission line 4b and the radiation electrode 11 as compared with a case where the second transmission line 4b and the radiation electrode 11 have different mesh structures. Therefore, it is possible to improve the antenna gain.

The second grounding electrode 6 has the mesh structure 8. Therefore, it is possible to reduce visibility of the second grounding electrode 6.

The grounding structure 7 has the mesh structure 8. Therefore, it is possible to reduce visibility of grounding structure 7. In the grounding structure 7, the grounding line 7b and the connection line 7e arranged on the second substrate 3B may have the mesh structure 8.

When the second transmission line 4b and the grounding structure 7 have the mesh structure 8, an electric field is easily transmitted to the outside in the fourth direction (Y direction). Therefore, isolation characteristics may deteriorate as compared with a case where the second transmission line 4b and the grounding structure 7 do not have the mesh structure 8. However, as described above, the size W4 of the second transmission line 4b can be set based on the size W1 of the first transmission line 4a smaller than the size W2 of the connection conductor 4d. Therefore, the gap I between the adjacent second transmission lines 4b can be increased without changing the interval d between the plurality of second transmission lines 4b. Therefore, the width of the grounding line 7b (the size of the grounding line 7b in the second direction) can be increased without changing the distance between the grounding line 7b and the second transmission line 4b. Accordingly, even when the isolation characteristics deteriorate due to the mesh structure 8, the isolation characteristics can be improved as a whole. On the other hand, since the interval d between the plurality of second transmission lines 4b can be narrowed without changing the gap I between the adjacent second transmission lines 4b, an area required for mounting the plurality of second transmission lines 4b can be reduced with the isolation characteristics maintained. Thus, a substrate area of the second substrate 3B can be reduced.

The antenna substrate 10C is different from the antenna substrate 10B according to the third embodiment in that the dielectric layer 30 of the second substrate 3B is transparent to visible light. The dielectric layer 30 can be formed of, for example, well-known glass or transparent resin. Examples of the transparent resin include organic insulating materials such as polyester-based resins such as polyethylene terephthalate, acryl-based resins such as polymethyl methacrylate, polycarbonate-based resins, polyimide-based resins, or polyolefin-based resins such as cycloolefin polymers, and cellulose-based resin materials such as triacetyl cellulose.

In the antenna substrate 10C, it is possible to reduce visibility of each of the second substrate 3B, the second transmission line 4b, the radiation electrode 11, the second grounding electrode 6, and the grounding structure 7. Therefore, the second substrate 3B can be disposed to overlap a display or the like seen by a person, for example, and the degree of freedom in disposition of antenna substrate 10C can be improved.

### [1.4.2 Effects and Like]

In the substrate connection structure 1B of the antenna substrate 10C described above, the second transmission line 4b has the mesh structure 8. In this configuration, it is possible to reduce the visibility of the second transmission line 4b.

In the substrate connection structure 1B of the antenna substrate 10C, the second substrate 3B includes the second grounding electrode 6 on the side opposite to the first substrate 2B with respect to the second transmission line 4b. At least one of the second transmission line 4b and the second grounding electrode 6 has the mesh structure 8. In this configuration, it is possible to reduce visibility of at least one of the second transmission line 4b and the second grounding electrode 6.

In the antenna substrate 10C, the second transmission line 4b and the radiation electrode 11 have the mesh structure 8. In this configuration, it is possible to reduce the visibility of the second transmission line 4b and the radiation electrode 11.

In the antenna substrate 10C, the second transmission line 4b and the radiation electrode 11 have the same mesh structure 8. In this configuration, an antenna gain can be improved as compared with a case where the second transmission line 4b and the radiation electrode 11 have different mesh structures.

In the antenna substrate 10C, the mesh structure 8 includes the plurality of first linear conductors 8a extending in the third direction and parallel to each other, and the plurality of second linear conductors 8b extending in the fourth direction different from the third direction to intersect the plurality of first linear conductors 8a and parallel to each other. The third direction corresponds to the length direction of the second transmission line 4b, and the fourth direction does not correspond to the length direction of the second transmission line 4b. In this configuration, an antenna gain can be improved as compared with a case where the third direction does not correspond to the length direction of the second transmission line 4b.

### 1.5 Fifth Embodiment

### [1.5.1 Configuration]

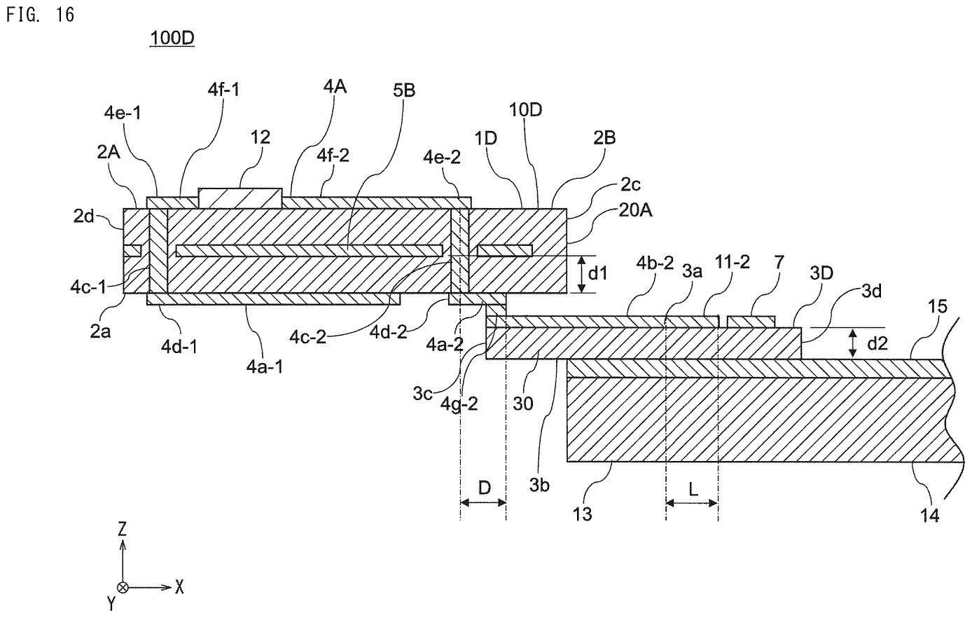

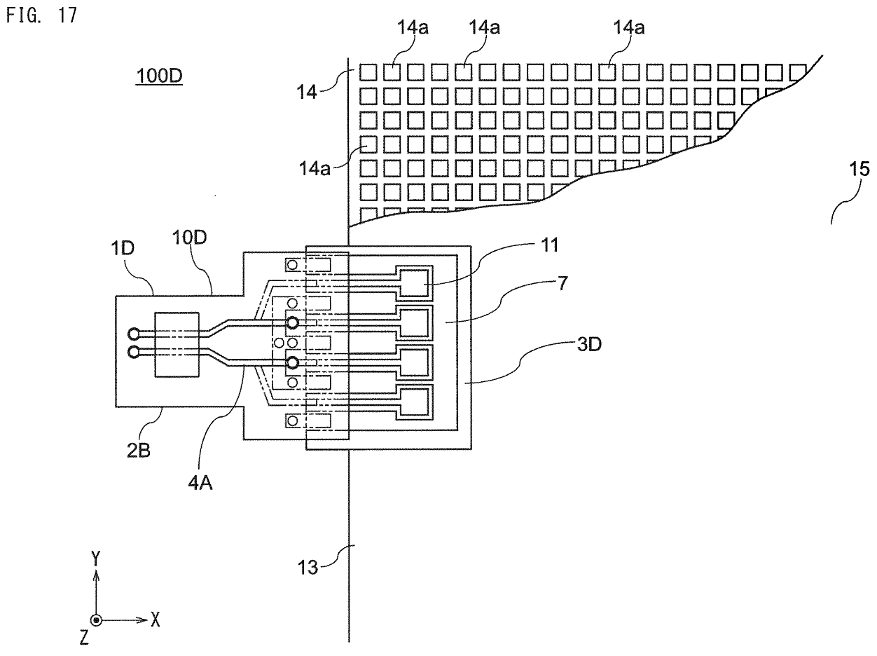

FIG. 16 is a cross-sectional view of a display device 100D according to a fifth embodiment. FIG. 17 is a plan view of the display device 100D of which a part is omitted.

The display device 100D includes the antenna substrate 10D and a display 13.

The display 13 includes a display element 14 and an input device 15.

The display element 14 is a liquid crystal display, an organic EL display, or the like. As illustrated in FIG. 17, the display element 14 includes a plurality of pixels 14a arranged in the fifth direction and a sixth direction intersecting the fifth direction. In the present embodiment, the fifth direction is the X direction, and the sixth direction is the Y direction.

The input device 15 is a transparent touch pad. As illustrated in FIG. 16, the input device 15 is disposed on a front surface of the display element 14, and configures a touch panel together with the display element 14.

Referring to FIGS. 16 and 17, the antenna substrate 10D includes a substrate connection structure 1D, a plurality of radiation electrodes 11-1 to 11-4, and a processing circuit 12. The substrate connection structure 1D includes the first substrate 2B, a second substrate 3D, and a transmission line 4B.

In the second substrate 3D, the dielectric layer 30 is transparent. The dielectric layer 30 can be formed of, for example, well-known glass or transparent resin. The second substrate 3D does not include the second grounding electrode 6. The antenna substrate 10D is mounted on the display 13 such that the fourth surface 3b of the second substrate 2D faces the input device 15 of the display 13. In this configuration, the input device 15 acts as a second grounding electrode.

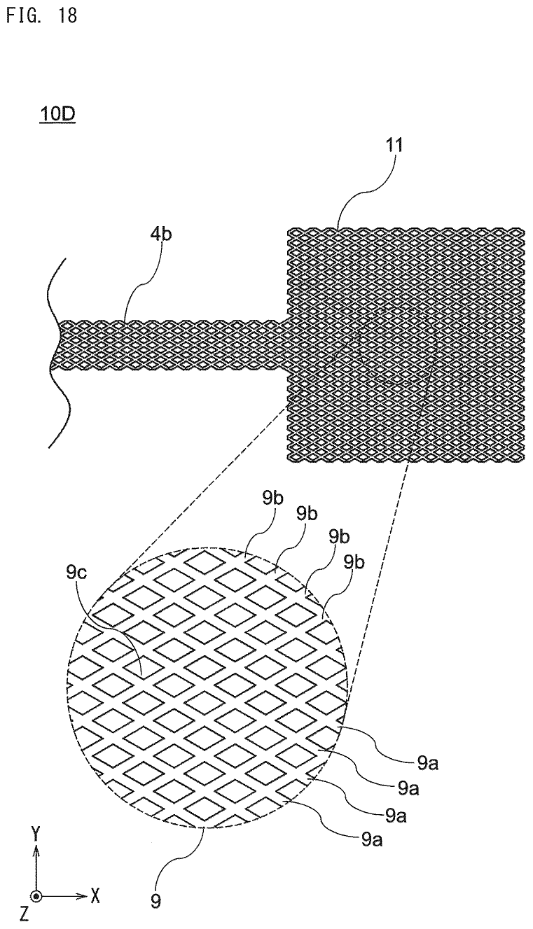

FIG. 18 is a plan view of the second transmission line 4b and the radiation electrode 11 of the antenna substrate 10D. In the antenna substrate 10D, the second transmission line 4b, the radiation electrode 11, and the grounding structure 7 have a mesh structure 9.

The mesh structure 9 includes a plurality of first linear conductors 9a and a plurality of second linear conductors 9b intersecting the plurality of first linear conductors 9a. The plurality of first linear conductors 9a are parallel to each other. The plurality of first linear conductors 9a extend in the third direction. The plurality of second linear conductors 9b are parallel to each other. The plurality of second linear conductors 9b extend in a fourth direction different from the third direction. In the present embodiment, each of the third and fourth directions is a direction different from any of the length direction (X direction), the fifth direction (X direction), and the sixth direction (Y direction) of the second transmission line 4b. For example, the third direction is a direction inclined by 30° with respect to the length direction (X direction) of the second transmission line 4b, and the fourth direction is a direction inclined by 60° with respect to the third direction. Any angles that avoid Moiré patterns with the display pixels may be used. Accordingly, as compared with the mesh structure 8, the mesh structure 9 becomes inconspicuous with respect to the pixel 14a of the display 13, and the visibility of the mesh structure 9 in the entire display device 100D is diminished.

In the mesh structure 9, the adjacent first linear conductor 9a and the adjacent second linear conductor 9b define one opening 9c. The plurality of openings 9c are regularly arranged in the third and fourth directions. Due to presence of the plurality of openings 9c, the visibility of the mesh structure 9 itself deteriorates. That is, the mesh structure 9 is hardly visible to the naked eye. As an example, the width of the first linear conductor 9a and the width of the second linear conductor 9b are 1 μm, and the interval between the first linear conductors 9a and the interval between the second linear conductors 9b are 100 μm. A ratio of a total area of the plurality of openings 9c to an area of a region where the mesh structure 9 is arranged is preferably 80% or more. Transmittance of visible light of the mesh structure 9 is preferably 80% or more.

### [1.5.2 Effects and Like]

The display device 100D described above includes the antenna substrate 10D and the display 13 disposed on the second substrate 3D on the side opposite to the first substrate 2A. This configuration enables easy adjustment of impedance of the transmission line 4.

In the display device 100D, the second transmission line 4b and the radiation electrode 11 have the same mesh structure 9. The mesh structure 9 includes a plurality of first linear conductors 9a extending in the third direction and parallel to each other, and the plurality of second linear conductors 9b extending in the fourth direction different from the third direction and parallel to each other to intersect the plurality of first linear conductors 9a. The display 13 includes a plurality of pixels 14a arranged in the fifth direction and the sixth direction intersecting the fifth direction. Each of the third and fourth directions is a direction different from any of the length direction, the fifth direction, and the sixth direction of the second transmission line 4b. This configuration can reduce visibility of the second transmission line 4b and the radiation electrode 11 as compared with a case where the third or fourth direction matches any of the length direction, fifth direction, and sixth directions of the second transmission line 4b. Furthermore, in this configuration, an antenna gain can be improved as compared with a case where the second transmission line 4b and the radiation electrode 11 have different mesh structures.

### 2. Modifications

Embodiments of the present disclosure are not limited to the above embodiments. As long as the object of the present disclosure can be achieved, the above embodiments can be variously modified according to design or the like. The modifications of the above embodiments will be listed below. The modifications to be described below can be appropriately combined and applied.

Hereinafter, the reference numerals used in the first embodiment will be referred to even when any of the first to fifth embodiments described above can be applied, but this is merely for simplifying the description, and is not intended to exclude application to the second to fifth embodiments.

In a modification, the shapes and dimensions of the first substrate 2 and the second substrate 3 may be appropriately changed. As an example, the first substrate 2 and the plurality of dielectric layers may be provided, and the third transmission line 4f may be located in a different dielectric layer instead of the third surface 2b. In this case, the through-hole wiring 4c can be configured as a via hole wiring instead of a through-hole wiring.

In a modification, the configuration of the transmission line 4 is not limited to the above examples. In the transmission line 4, the number, arrangement, and shape of each of the first transmission line 4a, the second transmission line 4b, the through-hole wiring 4c, the connection conductors 4d and 4e, or the third transmission line 4f may be appropriately changed.

In a modification, the transmission line 4 may include the plurality of second transmission lines 4b. In this case, all of the plurality of second transmission lines 4b may be parallel to each other, or two or more of the plurality of second transmission lines 4b may be parallel to each other.

In a modification, the shapes and dimensions of the first grounding electrode 5 and the second grounding electrode 6 may be appropriately changed. The positions of the first grounding electrode 5 and the second grounding electrode 6 may be changed. The second grounding electrode 6 may be located in the dielectric layer 30 of the second substrate 3. In this case, the distance d2 is not a distance (that is, the thickness of the second substrate 3) between the second surface 3a and the fourth surface 3b of the dielectric layer 30 of the second substrate 3, but is a distance from the second surface 3a to the second grounding electrode 6 in the dielectric layer 30. The first grounding electrode 5 and the second grounding electrode 6 can be omitted.

In a modification, the grounding structure 7 may include only one of the grounding lines 7a-1 to 7a-5 or the grounding lines 7b-1 to 7b-5. That is, the transmission line 4 may include grounding lines on both sides of at least one of the first transmission line 4a and the second transmission line 4b in the second direction. The transmission line 4 may not have the grounding structure 7.

In a modification, it is not necessary that all of the second transmission line 4b, the second grounding electrode 6, the grounding structure 7, and the radiation electrode 11 have the mesh structure 8 or 9. Any one of the second transmission line 4b, the second grounding electrode 6, the grounding structure 7, and the radiation electrode 11 may have the mesh structure 8 or 9.

In a modification, a frequency band of wireless communication in which the radiation electrode 11 is used is not particularly limited. For example, the frequency band may be selected from well-known frequency bands such as a frequency band of wireless communication by UWB, a frequency band of Bluetooth (registered trademark), a frequency band of wireless communication by Wi-Fi, a midband of a 2G (second generation mobile communication) standard, a low band of a 4G (fourth generation mobile communication) standard, and a low band of a 5G (fifth generation mobile communication) standard. The 2G standard is, for example, the Global System for Mobile Communications (GSM) (registered trademark) standard. The 4G standard is, for example, the 3GPP (registered trademark) Long Term Evolution (LTE) standard. The 5G standard is, for example, 5G New Radio (NR). The frequency band may be selected from frequency bands used for various communication standards such as a wireless LAN, specific low power radio, and near field communication.

### 3. Aspects

As apparent from the above embodiments and modifications, the present disclosure includes the following aspects.

### [Aspect 1]

A substrate connection structure comprising:
a first substrate;
a second substrate partially facing the first substrate when viewed in a thickness direction of the first substrate; and
a transmission line extending over the first and second substrates;
wherein the transmission line includes a first transmission line on a first surface of the first substrate facing the second substrate, a second transmission line on a second surface of the second substrate facing the first substrate, a through-hole wiring located at a position not overlapping with the second transmission line when viewed in a thickness direction of the first substrate, and a connection conductor on the first surface and connected to the through-hole wiring,
the first transmission line extends from the connection conductor to the second transmission line and is connected to the second transmission line, and
a size of the first transmission line is less than a size of the connection conductor in a second direction orthogonal to a first direction in which the first transmission line extends from the connection conductor to the second transmission line when viewed in the thickness direction of the first substrate.

### [Aspect 2]

The substrate connection structure according to aspect 1, wherein a size of the first transmission line is less than a size of the through-hole wiring in the second direction.

### [Aspect 3]

The substrate connection structure according to aspect 1 or 2, wherein ends of the first and second substrates face each other when viewed in the thickness direction of the first substrate.

### [Aspect 4]

The substrate connection structure according to any one of aspects 1 to 3, wherein the through-hole wiring is at a position not overlapping with the second substrate when viewed in the thickness direction of the first substrate.

### [Aspect 5]

The substrate connection structure according to any one of aspects 1 to 4,
wherein the transmission line includes a plurality of the second transmission lines, and
two or more of the plurality of second transmission lines are parallel to each other.

### [Aspect 6]

The substrate connection structure according to any one of aspects 1 to 5,
wherein the transmission line includes a plurality of the first transmission lines,
the transmission line includes a parallel running line that is separated from a first first transmission line among the plurality of first transmission lines in the thickness direction of the first substrate and is connected to a second first transmission line different from the first first transmission line among the plurality of first transmission lines via the through-hole wiring,
the first substrate includes a first grounding electrode, and
at least a part of the first grounding electrode is located between the first first transmission line and the parallel running line in the thickness direction of the first substrate.

### [Aspect 7]

The substrate connection structure according to any one of aspects 1 to 5,
wherein the transmission line includes a plurality of the first transmission lines,
the transmission line includes a parallel running line that is separated from a first first transmission line among the plurality of first transmission lines in the thickness direction of the first substrate and is connected to a second first transmission line different from the first first transmission line among the plurality of first transmission lines via the through-hole wiring,
the first substrate includes a first grounding electrode, and
at least a part of the first grounding electrode, at least a part of the first first transmission line, and at least a part of the parallel running line overlap each other when viewed in the thickness direction of the first substrate.

### [Aspect 8]

The substrate connection structure according to aspect 6 or 7,
wherein the transmission line includes a plurality of the second transmission lines, and
the first first transmission line and the second first transmission line are connected to two adjacent second transmission lines among the plurality of second transmission lines.

### [Aspect 9]

The substrate connection structure according to any one of aspects 6 to 8,
wherein a dielectric constant of the first substrate is higher than a dielectric constant of the second substrate,
a distance between the first transmission line and the first grounding electrode in the thickness direction of the first substrate is shorter than a distance between the second transmission line and a second grounding electrode on a side of the second transmission line opposite to the first substrate in the thickness direction of the second substrate, and
the first grounding electrode does not overlap the second substrate when viewed in the thickness direction of the first substrate.

### [Aspect 10]

The substrate connection structure according to any one of aspects 6 to 8,
wherein a dielectric constant of the first substrate is lower than a dielectric constant of the second substrate,
a distance between the first transmission line and the first grounding electrode in the thickness direction of the first substrate is longer than a distance between the second transmission line and a second grounding electrode on a side of the second transmission line opposite to the first substrate in the thickness direction of the second substrate, and
at least a part of the first grounding electrode overlaps the second substrate when viewed in the thickness direction of the first substrate.

### [Aspect 11]

The substrate connection structure according to any one of aspects 1 to 10, wherein the second transmission line has a mesh structure.

### [Aspect 12]

The substrate connection structure according to any one of aspects 1 to 10,
wherein the second substrate includes a second grounding electrode on a side of the second transmission line opposite to the first substrate, and
at least one of the second transmission line and the second grounding electrode has a mesh structure.

### [Aspect 13]

The substrate connection structure according to any one of aspects 1 to 12, wherein the transmission line includes a grounding line on both sides of at least one of the first transmission line and the second transmission line in the second direction.

### [Aspect 14]

An antenna substrate comprising:
the substrate connection structure according to any one of aspects 1 to 13; and
a radiation electrode on the second substrate, the radiation electrode being connected to the second transmission line.

### [Aspect 15]

The antenna substrate according to aspect 14,
wherein D<L is satisfied,
L is a size of the radiation electrode in a predetermined direction along a polarization direction of a radio wave emitted from the radiation electrode, and
D is a distance between a center of the through-hole wiring in the predetermined direction and an end of the first transmission line on a side of the second transmission line.

### [Aspect 16]

The antenna substrate according to aspect 14,
wherein D<L is satisfied,
L is a size of the radiation electrode in a predetermined direction along a linear line connecting a feeding point and a center of the radiation electrode, and
D is a distance between a center of the through-hole wiring in the predetermined direction and an end of the first transmission line on a side of the second transmission line.

### [Aspect 17]

The antenna substrate according to any one of aspects 14 to 16, wherein the second transmission line and the radiation electrode have a mesh structure.

### [Aspect 18]

The antenna substrate according to aspect 17, wherein the second transmission line and the radiation electrode have an identical mesh structure.

### [Aspect 19]

The antenna substrate according to aspect 18,
wherein the mesh structure includes a plurality of first linear conductors extending in a third direction and parallel to each other, and a plurality of second linear conductors parallel to each other and extending in a fourth direction different from the third direction so as to intersect the plurality of first linear conductors,
wherein the third direction corresponds to a length direction of the second transmission line, and
the fourth direction does not correspond to a length direction of the second transmission line.

### [Aspect 20]

A display device comprising:
the antenna substrate according to any one of aspects 14 to 16; and
a display disposed on a side of the second substrate opposite to the first substrate.

### [Aspect 21]

The display device according to aspect 20,
wherein the second transmission line and the radiation electrode have an identical mesh structure,
the mesh structure includes
   a plurality of first linear conductors extending in a third direction and parallel to each other, and
   a plurality of second linear conductors parallel to each other and extending in a fourth direction different from the third direction so as to intersect the plurality of first linear conductors,
the display includes a plurality of pixels arranged in a fifth direction and a sixth direction intersecting the fifth direction, and
each of the third and fourth directions is a direction different from all of a length direction of the second transmission line, the fifth direction, and the sixth direction.

Aspects 2 to 13, 15 to 19 and 21 are optional and not essential.

### INDUSTRIAL APPLICABILITY

The present disclosure can be applied to substrate connection structures and antenna substrates. In particular, the present disclosure is applicable to a substrate connection structure including a transmission line extending over substrates, and an antenna substrate including the substrate connection structure.

### REFERENCE SIGNS LIST

1, 1A, 1B Substrate Connection Structure
2, 2a, 2b First Substrate
2a First Surface
2b Third Surface
2c First End
3, 3a, 3b Second Substrate
3a Second Surface
3b Fourth Surface
4, 4a Transmission Line
4a, 4a-1 To 4a-4 First Transmission Line
4b, 4b-1 To 4b-4 Second Transmission Line
4c, 4c-1 To 4c-4 Through-Hole Wiring
4d, 4d-1 To 4d-4 Connection Conductor
4f, 4f-1, 4f-4 Third Transmission Line
4f-2, 4f-3 Third Transmission Line (Parallel Running Line)
5, 5b First Grounding Electrode
6 Second Grounding Electrode (Grounding Conductor)
7 Grounding Structure
7a-1 To 7a-5 Grounding Line
7b-1 To 7b-5 Grounding Line
8 Mesh Structure
8a First Linear Conductor
8b Second Linear Conductor
9 Mesh Structure
9a First Linear Conductor
9b Second Linear Conductor
10a, 10b, 10c, 10d Antenna Substrate
11, 11-1 To 11-4 Radiation Electrode
13 Display
14a Pixel
15 Input Device (Second Grounding Electrode)
100D Display Device

What is claimed is:

1. A substrate connection structure comprising:
a first substrate;
a second substrate partially facing the first substrate when viewed in a thickness direction of the first substrate; and
a transmission line extending over the first and second substrates, wherein
the transmission line includes a first transmission line on a first surface of the first substrate facing the second substrate, a second transmission line on a second surface of the second substrate facing the first substrate, a through-hole wiring located at a position not overlapping with the second transmission line when viewed in a thickness direction of the first substrate, and a connection conductor on the first surface and connected to the through-hole wiring,
the first transmission line extends from the connection conductor to the second transmission line and is connected to the second transmission line, and
a size of the first transmission line is less than a size of the connection conductor in a second direction orthogonal to a first direction in which the first transmission line extends from the connection conductor to the second transmission line when viewed in the thickness direction of the first substrate.

2. The substrate connection structure according to claim 1, wherein the size of the first transmission line is less than a size of the through-hole wiring in the second direction.

3. The substrate connection structure according to claim 1, wherein an end of the first and an end of the second substrates face each other when viewed in the thickness direction of the first substrate.

4. The substrate connection structure according to claim 1, wherein the through-hole wiring is at a position not overlapping with the second substrate when viewed in the thickness direction of the first substrate.

5. The substrate connection structure according to claim 1, wherein
the transmission line includes a plurality of the second transmission lines, and
two or more of the plurality of second transmission lines are parallel to each other.

6. The substrate connection structure according to claim 1, wherein
the transmission line includes a plurality of the first transmission lines,
the transmission line includes a parallel running line that is separated from a first first transmission line among the plurality of first transmission lines in the thickness direction of the first substrate and is connected to a second first transmission line different from the first first transmission line among the plurality of first transmission lines via the through-hole wiring,
the first substrate includes a first grounding electrode, and
at least a part of the first grounding electrode is located between the first first transmission line and the parallel running line in the thickness direction of the first substrate.

7. The substrate connection structure according to claim 1, wherein
the transmission line includes a plurality of the first transmission lines,
the transmission line includes a parallel running line that is separated from a first first transmission line among the plurality of first transmission lines in the thickness direction of the first substrate and is connected to a second first transmission line different from the first first transmission line among the plurality of first transmission lines via the through-hole wiring,
the first substrate includes a first grounding electrode, and
at least a part of the first grounding electrode, at least a part of the first first transmission line, and at least a part of the parallel running line overlap each other when viewed in the thickness direction of the first substrate.

8. The substrate connection structure according to claim 6, wherein
the transmission line includes a plurality of the second transmission lines, and
the first first transmission line and the second first transmission line are connected to two adjacent second transmission lines among the plurality of second transmission lines.

9. The substrate connection structure according to claim 6, wherein
a dielectric constant of the first substrate is higher than a dielectric constant of the second substrate,
a distance between the first transmission line and the first grounding electrode in the thickness direction of the first substrate is shorter than a distance between the second transmission line and a second grounding electrode on a side of the second transmission line opposite to the first substrate in the thickness direction of the second substrate, and
the first grounding electrode does not overlap the second substrate when viewed in the thickness direction of the first substrate.

10. The substrate connection structure according to claim 6,
wherein a dielectric constant of the first substrate is lower than a dielectric constant of the second substrate,
a distance between the first transmission line and the first grounding electrode in the thickness direction of the first substrate is longer than a distance between the second transmission line and a second grounding electrode on a side of the second transmission line opposite to the first substrate in the thickness direction of the second substrate, and
at least a part of the first grounding electrode overlaps the second substrate when viewed in the thickness direction of the first substrate.

11. The substrate connection structure according to claim 1, wherein the second transmission line has a mesh structure.

12. The substrate connection structure according to claim 1, wherein
the second substrate includes a second grounding electrode on a side of the second transmission line opposite to the first substrate, and
at least one of the second transmission line and the second grounding electrode has a mesh structure.

13. The substrate connection structure according to claim 1, wherein the transmission line includes a grounding line on both sides of at least one of the first transmission line and the second transmission line in the second direction.

14. An antenna substrate comprising:
the substrate connection structure according to claim 1; and
a radiation electrode on the second substrate, the radiation electrode being connected to the second transmission line.

15. The antenna substrate according to claim 14,
wherein D<L is satisfied,
L is a size of the radiation electrode in a predetermined direction along a linear line connecting a feeding point and a center of the radiation electrode, and
D is a distance between a center of the through-hole wiring in the predetermined direction and an end of the first transmission line on a side of the second transmission line.

16. The antenna substrate according to claim 14, wherein the second transmission line and the radiation electrode have a mesh structure.

17. The antenna substrate according to claim 16, wherein the second transmission line and the radiation electrode have an identical mesh structure.

18. The antenna substrate according to claim 17,
wherein the mesh structure includes a plurality of first linear conductors extending in a third direction and parallel to each other, and a plurality of second linear conductors parallel to each other and extending in a fourth direction different from the third direction so as to intersect the plurality of first linear conductors,
wherein the third direction corresponds to a length direction of the second transmission line, and
the fourth direction does not correspond to a length direction of the second transmission line.

19. A display device comprising:
the antenna substrate according to claim 14; and
a display disposed on a side of the second substrate opposite to the first substrate.

20. The display device according to claim 19,
wherein the second transmission line and the radiation electrode have an identical mesh structure,
the mesh structure includes
a plurality of first linear conductors extending in a third direction and parallel to each other, and
a plurality of second linear conductors parallel to each other and extending in a fourth direction different from the third direction so as to intersect the plurality of first linear conductors,
the display includes a plurality of pixels arranged in a fifth direction and a sixth direction intersecting the fifth direction, and
each of the third and fourth directions is a direction different from all of a length direction of the second transmission line, the fifth direction, and the sixth direction.
